(19) United States
(12) Patent Application Publication
(10) Pub. No.: US 2026/0305462 A1
(43) Pub. Date: Oct. 1, 2026

(54) SUBSTRATE LAYERED BODY PRODUCING METHOD AND SUBSTRATE LAYERED BODY

(71) Applicant: MITSUI CHEMICALS, INC., Chuo-ku, Tokyo (JP)

(72) Inventors: Satoshi INADA, Sodegaura-shi, Chiba (JP); Yasuhisa KAYABA, Sodegaura-shi, Chiba (JP); Yuzo NAKAMURA, Sodegaura-shi, Chiba (JP)

(73) Assignee: MITSUI CHEMICALS, INC., Chuo-ku, Tokyo (JP)

(21) Appl. No.: 18/880,342

(22) PCT Filed: Jul. 4, 2023
(86) PCT No.: PCT/JP2023/024825

§ 371 Date: Dec. 31, 2024

(30) Foreign Application Priority Data
Jul. 6, 2022 (JP) 2022-109052

(51) Int. Cl. H10W 80/00; H10P 58/00; H10W 90/00; H10W 90/10

(52) U.S. Cl. CPC H10W 80/327; H10P 58/00; H10W 80/016; H10W 80/023; H10W 80/211; H10W 80/312; H10W 80/334; H10W 90/10; H10W 90/792

(57) ABSTRACT

A method of producing a substrate layered body, including: preparing: a first layered body in which a first resin layer, a first substrate, and a first inorganic material layer are layered in this order, the first resin layer is disposed at one surface, and the first inorganic material layer is disposed at another surface; and a second layered body in which a second resin layer, a second substrate, and a second inorganic material layer are layered in this order, the second resin layer is disposed at one surface, and the second inorganic material layer is disposed at another surface; bringing the first resin layer of the first layered body and the second inorganic material layer of the second layered body into contact with each other, thereby layering the first layered body and the second layered body; and heating the first layered body and the second layered body.

### TECHNICAL FIELD

The present disclosure relates to a method of producing a substrate layered body, and a substrate layered body.

### BACKGROUND ART

As electronic devices become smaller and lighter and have higher performance, higher integration of semiconductor chips and the like is required. However, it is difficult to sufficiently meet the demand with miniaturization of the circuit. Therefore, in recent years, a method has been proposed in which a plurality of semiconductor substrates (wafers), semiconductor chips, and the like are layered vertically to achieve a high integration by forming a multilayer three-dimensional structure. As a method of layering semiconductor substrates (wafers), semiconductor chips, and the like (hereinafter sometimes referred to as “semiconductor substrates and the like”), methods such as direct bonding between substrates and methods using an adhesive have been proposed (e.g., Patent Literature 1 to 3).
Patent Literature 1: Japanese Patent Application Laid-Open (JP-A) No. H04-132258
Patent Literature 2: Japanese Patent Application Laid-Open (JP-A) No. 2010-226060
Patent Literature 3: Japanese Patent Application Laid-Open (JP-A) No. 2016-047895

### SUMMARY OF INVENTION

### Technical Problem

Direct bonding has a problem that voids are likely to occur due to minute irregularities caused by wiring and the like on the substrate surface, as well as particles. As a method of layering semiconductor substrates and the like, a method of bonding inorganic materials such as silicon oxide provided on substrates is also envisioned. However, the method of bonding inorganic materials on substrates together has a problem of easily generating voids similar to direct bonding.

Meanwhile, in a case in which bonding is performed using an adhesive, the adhesive is applied to the surfaces of substrates and then dried to a semi-cured state, followed by affixing the substrates together. At this time, in order to suppress the occurrence of voids, it is considered to apply an adhesive to the bonding surfaces of the substrates to form an adhesive layer, and then bond the adhesive layers together. Furthermore, from the viewpoint of increasing the bonding strength when affixing the bonding surfaces of substrates together, it is preferable to perform a surface activation treatment such as plasma treatment or fast atom bombardment (FAB) treatment on the bonding surfaces of the substrates.

However, in the case of performing a surface activation treatment on the adhesive layer, the resin contained in the adhesive layer may be affected by the surface activation treatment, and the adhesive layer may be altered in quality, thereby affecting its reliability. Alternatively, the bonding surfaces of substrates may be cleaned to remove particles and the like thereon, but when an adhesive layer is provided on the bonding surfaces, there is a problem that the cleaning method is limited. In view of the above, a method of producing a substrate layered body, in which restrictions on the surface activation and cleaning treatment methods for the bonding surfaces of substrates are reduced, even when a resin layer is provided at the bonding surfaces of the substrates, is desirable.

One aspect of the present invention has been made in consideration of the above problems, and an object thereof is to provide a method of producing a substrate layered body, in which a resin layer is provided at the bonding surfaces of substrates and restrictions on the surface activation and cleaning treatment methods for the bonding surfaces of substrates are reduced, and a layered body that can be used for this production method.

### Solution to Problem

Specific means for solving the above problem are as follows.

<1> A method of producing a substrate layered body, including:
a step A of preparing: a first layered body in which a first resin layer, a first substrate, and a first inorganic material layer are layered in this order, the first resin layer is disposed at one surface, and the first inorganic material layer is disposed at another surface; and a second layered body in which a second resin layer, a second substrate, and a second inorganic material layer are layered in this order, the second resin layer is disposed at one surface, and the second inorganic material layer is disposed at another surface;
a step B of bringing the first resin layer of the first layered body and the second inorganic material layer of the second layered body into contact with each other, thereby layering the first layered body and the second layered body; and
a step C of heating the first layered body and the second layered body at 100° C. or more after the step B.

<2> The method of producing a substrate layered body according to <1>,
in which the first layered body includes an electrode at a part of a surface of the first resin layer and a part of a surface of the first inorganic material layer, and
in which the second layered body includes an electrode at a part of a surface of the second resin layer and a part of a surface of the second inorganic material layer.

<3> The method of producing a substrate layered body according to <2>, the method including a step of performing a surface activation treatment on the second inorganic material layer before the step B.

<4> The method of producing a substrate layered body according to <1>, the method including, after the step C, a step of creating a through hole in the first layered body and the second layered body from a surface on a side of the first inorganic material layer toward a surface on a side of the second resin layer and forming an electrode penetrating the first layered body and the second layered body in the through hole.

<5> The method of producing a substrate layered body according to any one of <1> to <4>, the method including a step of cleaning the second inorganic material layer before the step B.

<6> The method of producing a substrate layered body according to any one of <1> to <5>, the method including a step of providing a surface protective layer at the second inorganic material layer before the step B.

<7> The method of producing a substrate layered body according to any one of <1> to <6>, in which, before the first resin layer and the second inorganic material layer are brought into contact with each other in the step B, the first resin layer has a composite elastic modulus at 23° C. of from 0.1 GPa to 20 GPa.

<8> The method of producing a substrate layered body according to any one of <1> to <7>, in which, before the first resin layer and the second inorganic material layer are brought into contact with each other in the step B, the first resin layer has a curing rate of from 70% to 100%.

<9> The method of producing a substrate layered body according to any one of <1> to <8>, in which, before the first resin layer and the second inorganic material layer are brought into contact with each other in the step B, the first resin layer has a surface roughness (Ra) of from 0.01 nm to 1.2 nm.

<10> The method of producing a substrate layered body according to any one of <1> to <9>, in which the first resin layer has at least one functional group selected from the group consisting of a silanol group, an amino group, an epoxy group, a hydroxyl group, and a functional group having an unsaturated bond, on a surface thereof.

<11> The method of producing a substrate layered body according to any one of <1> to <10>, in which the first resin layer includes:
a siloxane bond; and
at least one selected from the group consisting of an ester bond, an ether bond, an amide bond, and an imide bond.

<12> The method of producing a substrate layered body according to any one of <1> to <11>, in which the second inorganic material layer contains at least one element selected from the group consisting of Si, Ga, Ge, and As.

<13> A substrate layered body, including:
a first layered body having a first resin layer, a first substrate, and a first inorganic material layer in this order, in which the first resin layer is disposed at one surface and the first inorganic material layer is disposed at another surface; and
a second layered body having a second resin layer, a second substrate, and a second inorganic material layer in this order, in which the second resin layer is disposed at one surface and the second inorganic material layer is disposed at another surface,
in which the first layered body and the second layered body are layered via the first resin layer of the first layered body and the second inorganic material layer of the second layered body.

<14> The substrate layered body according to <13>,
in which the first layered body includes an electrode at a part of a surface of the first resin layer and a part of a surface of the first inorganic material layer, and
in which the second layered body includes an electrode at a part of a surface of the second resin layer and a part of a surface of the second inorganic material layer.

### Advantageous Effects of Invention

One aspect of the present invention can provide a method of producing a substrate layered body, in which a resin layer is provided at the bonding surfaces of substrates and restrictions on the surface activation and cleaning treatment methods for the bonding surfaces of substrates are reduced, and a layered body that can be used for this production method.

### BRIEF DESCRIPTION OF DRAWINGS

FIGS. 1a to 1h are schematic configuration diagrams showing Example 1 of the method of producing a substrate layered body of the present disclosure.

FIGS. 2a to 2i are schematic configuration diagrams showing Example 2 of the method of producing a substrate layered body of the present disclosure.

### DESCRIPTION OF EMBODIMENTS

In the present disclosure, a numerical range expressed using “to” means a range that includes the numerical values before and after “to” as the lower and upper limits.

In the present disclosure, the upper or lower limit value described in one numerical range may be replaced with the upper or lower limit value of another numerical range described stepwise, within numerical ranges described stepwise. In addition, the upper or lower limit value within a numerical range described in the present disclosure may be replaced with a value indicated in the Examples.

In the present disclosure, the “substrate layered body” means a layered body having a structure in which two substrates, i.e., first and second substrates are bonded via a first resin layer and a second inorganic material layer. The substrate layered body may have three or more substrates or a structure in which two of three or more substrates are bonded via a first resin layer and a second inorganic material layer.

In the present disclosure, the term “substrate” refers to “at least one of a first substrate or a second substrate”, the term “resin layer” refers to “at least one of a first resin layer or a second resin layer”, and the term “inorganic material layer” refers to “at least one of a first inorganic material layer or a second inorganic material layer”.

The method of producing a substrate layered body of the present disclosure includes: a step A of preparing: a first layered body in which a first resin layer, a first substrate, and a first inorganic material layer are layered in this order, the first resin layer is disposed at one surface, and the first inorganic material layer is disposed at another surface; and a second layered body in which a second resin layer, a second substrate, and a second inorganic material layer are layered in this order, the second resin layer is disposed at one surface, and the second inorganic material layer is disposed at another surface; a step B of bringing the first resin layer of the first layered body and the second inorganic material layer of the second layered body into contact with each other, thereby layering the first layered body and the second layered body; and a step C of heating the first layered body and the second layered body at 100° C. or more after the step B.

In the method of producing a substrate layered body of the present disclosure, at least two layered bodies, in which a resin layer, a substrate, and an inorganic material layer are layered in this order, are prepared in the step A. The two layered bodies prepared are layered by bringing the resin layer (first resin layer) of one layered body into contact with the inorganic material layer (second inorganic material layer) of another layered body in the step B. Then, in the step C, the two layered bodies layered are heated at 100° C. or more, thereby obtaining a substrate layered body having a structure in which bonding has been achieved via the resin layer (first resin layer) and the inorganic material layer (second inorganic material layer). In the present disclosure, after performing a surface activation treatment, a cleaning treatment, and the like on the surface of the inorganic material layer, the two substrates can be bonded via the resin layer and the inorganic material layer. This makes it possible to increase the bonding strength of the bonding surfaces and remove particles and the like adhering to the surface of the inorganic material layer without carrying out surface activation treatment, cleaning treatment, and the like on the surface of the resin layer. Thus, a method of producing a substrate layered body, in which a resin layer is provided at the bonding surfaces of substrates and restrictions on the surface activation and cleaning treatment methods for the bonding surfaces of substrates are reduced, is provided.

### [Step A]

The method of producing a substrate layered body of the present disclosure includes a step A of preparing a first layered body and a second layered body. The first layered body includes a first resin layer, a first substrate, and a first inorganic material layer in this order, and the first resin layer is disposed at one surface and the first inorganic material layer is disposed at another surface. Similarly, the second layered body includes a second resin layer, a second substrate, and a second inorganic material layer in this order, the second resin layer is disposed at one surface, and the second inorganic material layer is disposed at another surface.

### (First Substrate and Second Substrate)

The materials for the first substrate and the second substrate are not particularly limited, and may be any commonly used materials. The materials of the first substrate and the second substrate may be the same as or different from each other.

The first substrate and the second substrate preferably contain at least one element selected from the group consisting of Si, Al, Ti, Zr, Hf, Fe, Ni, Cu, Ag, Au, Ga, Ge, Sn, Pd, As, Pt, Mg, In, Ta, and Nb. Examples of materials for the first substrate and the second substrate include: semiconductors: Si, InP, GaN, GaAs, InGaAs, InGaAlAs, SiC; oxides, carbides, and nitrides: borosilicate glass (e.g., PYREX (registered trademark)), quartz glass (SiO₂), sapphire, ZrO₂, Si₃N₄, AlN; piezoelectrics, dielectrics: BaTiO₃, LiNbO₃, SrTiO₃, diamond; and metals: Al, Ti, Fe, Cu, Ag, Au, Pt, Pd, Ta, Nb.

Other examples of materials for the first substrate and the second substrate may include: resins: polydimethylsiloxane (PDMS), epoxy resin, phenolic resin, polyimide, benzocyclobutene resin, and polybenzoxazole.

The first substrate and the second substrate may have a multi-layer structure. Examples thereof include: a structure in which an inorganic layer of silicon oxide, silicon nitride, SiCN (silicon carbonitride), or the like is formed on the surface of a silicon substrate or the like; a structure in which an organic layer of a polyimide resin, a polybenzoxazole resin, an epoxy resin, cyclotene (Dow Chemical Company Limited), an imide cross-linked siloxane resin, epoxy-modified siloxane, an organic-inorganic composite low-k material such as porous silica, organic crosslinked siloxane, or black diamond (Applied Materials), or the like is formed on the surface of a silicon substrate or the like; and a structure in which a composite of inorganic and organic materials is formed on a silicon substrate.

The main uses of each material are as follows:
Si for semiconductor memories, LSI stacks, CMOS image sensors, MEMS encapsulation, optical devices, LEDs, and the like;
SiO₂ for semiconductor memories, LSI stacks, MEMS sealing, microchannels, CMOS image sensors, optical devices, LEDs, and the like;
PDMS for microchannels;
InGaAlAs, InGaAs, InP for optical devices; and
InGaAlAs, GaAs, and GaN for LEDs and the like

The thicknesses of the first substrate and the second substrate are each independently preferably from 0.5 μm to 1 mm, more preferably from 1 μm to 900 μm, and still more preferably from 2 μm to 900 μm.

The shapes of the first substrate and the second substrate are not particularly limited.

For example, in a case in which the first substrate and the second substrate are a silicon substrate, it may be a silicon substrate on which an interlayer insulating layer (low-k film) is formed, and the silicon substrate may have fine grooves (recesses), fine through holes, and the like created therein.

In the method of producing a substrate layered body of the present disclosure, from the viewpoint of bonding strength, a surface treatment may be performed on at least one of a surface of the first substrate that comes into contact with the first resin layer or a surface of the second substrate that comes into contact with the second resin layer. For example, by performing the aforementioned surface treatment, at least one kind of functional group selected from the group consisting of a hydroxyl group, an epoxy group, a carboxy group, an amino group, and a mercapto group may be formed.

Examples of the above-described surface treatment include plasma treatment, chemical treatment, and ultraviolet (UV) ozone treatment.

The hydroxyl group can be provided on the surfaces of the first substrate and the second substrate by performing a surface treatment such as plasma treatment, chemical treatment, or ozone treatment such as UV ozone treatment on the surfaces.

It is preferable that the hydroxyl group is present in a state bonded to at least one element selected from the group consisting of Si, Al, Ti, Zr, Hf, Fe, Ni, Cu, Ag, Au, Ga, Ge, Sn, Pd, As, Pt, Mg, In, Ta, and Nb contained in the first substrate or the second substrate. It is preferable that a surface of the first substrate that comes into contact with the first resin layer and a surface of the second substrate that comes into contact with the second resin layer have a silanol group containing a hydroxyl group.

The epoxy group can be provided on the surfaces of the first substrate and the second substrate by performing a surface treatment such as silane coupling using epoxy silane on the surfaces.

The carboxy group can be provided on the surfaces of the first substrate and the second substrate by performing a surface treatment such as silane coupling using carboxysilane on the surfaces.

The amino group can be provided on the surfaces of the first substrate and the second substrate by performing a surface treatment such as silane coupling using aminosilane on the surfaces.

The mercapto group can be provided on the surfaces of the first substrate and the second substrate by performing a surface treatment such as silane coupling using mercaptosilane on the surfaces.

Furthermore, to increase bonding strength, a primer such as a silane coupling agent may be formed on the surface of at least one of the first substrate or the second substrate to which the resin material is applied.

### (First Resin Layer and Second Resin Layer)

The first resin layer is a layer disposed at one surface of the first substrate, and the second resin layer is a layer disposed at one surface of the second substrate. For example, the first resin layer and the second resin layer are formed by applying a resin composition containing a resin material to one surface of the first substrate and one surface of the second substrate and curing each of the resin composition layers formed.

Examples of a material contained in the resin composition include, but are not particularly limited to: materials in which a bond or a structure is formed by crosslinking, such as polyimide, polyamide, polyamideimide, parylene, polyarylene ether, tetrahydronaphthalene, and octahydroanthracene; materials in which a nitrogen ring-containing structure is formed, such as polybenzoxazal and polybenzoxazine; materials in which a bond or a structure, such as Si—O, is formed by crosslinking; and organic materials such as siloxane-modified compounds.

A resin material used for forming the first resin layer and a resin material used for forming the second resin layer may be the same as or different from each other.

Examples of the structure having an Si—O bond (siloxane bond) include structures represented by the following Formulas (1) to (3).

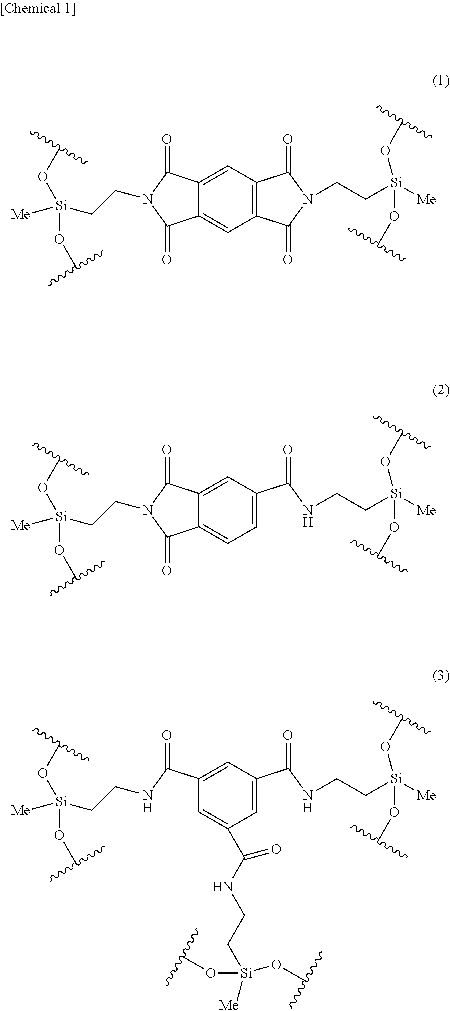 [SMILES: *O[Si](C)(CCn1c(=O)c2cc3c(=O)n(CC[Si](C)(O*)O*)c(=O)c3cc2c1=O)O* ; *O[Si](C)(CCNC(=O)c1ccc2c(c1)C(=O)N(CC[Si](C)(O*)O*)C2=O)O* ; *O[Si](C)(CCNC(=O)c1cc(C(=O)NCC[Si](C)(O*)O*)cc(C(=O)NCC[Si](C)(O*)O*)c1)O*]

In the structure having an Si—O bond (siloxane bond), the group bonded to Si may be substituted with an alkylene group, a phenylene group, or the like. For example, it may be a structure having (—O—)ₓ(R₁)_{y}Si—(R₂)—Si(R₁)_{y}(—O—)ₓ or the like (R₁ represents a methyl group or the like, R₂ represents an alkylene group, a phenylene group or the like, x and y each independently represent an integer of 0 or more, and x+y is 3).

Examples of materials in which an Si—O bond is formed by crosslinking include compounds represented by the following Formulas (4) and (5). Moreover, the structures represented by Formulas (1) and (2) can be produced, for example, by heating and reacting the compounds represented by Formulas (4) and (5).

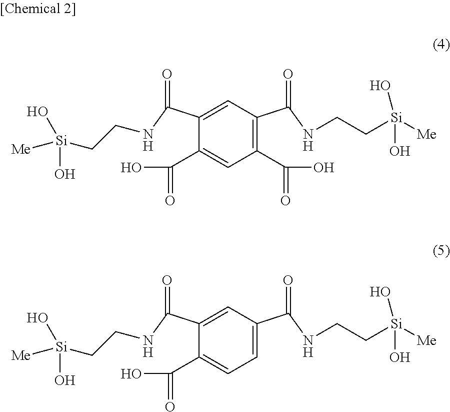 [SMILES: C[Si](O)(O)CCNC(=O)c1cc(C(=O)NCC[Si](C)(O)O)c(C(=O)O)cc1C(=O)O ; C[Si](O)(O)CCNC(=O)c1ccc(C(=O)O)c(C(=O)NCC[Si](C)(O)O)c1]

For example, in a case in which the resin material includes materials such as a polyimide, a polyamide, a polyamideimide, and the like whose bonds or structures are formed by crosslinking, it preferably includes a compound (A) containing a cationic functional group containing at least one of a primary nitrogen atom or a secondary nitrogen atom and having a weight average molecular weight of from 90 to 400,000; and a crosslinking agent (B) containing three or more —C(═O)OX groups (X is a hydrogen atom or an alkyl group having from 1 to 6 carbon atoms) in the molecule, in which of the three or more —C(═O)OX groups, one to six are —C(═O)OH groups, and having a weight average molecular weight of 200 or more and 2,000 or less.

### (Compound (A))

The compound (A) is a compound having a cationic functional group containing at least one of a primary nitrogen atom or a secondary nitrogen atom and having a weight average molecular weight of from 90 to 400,000. The cationic functional group is not particularly limited as long as it is a functional group that can be positively charged and contains at least one of a primary nitrogen atom or a secondary nitrogen atom.

Furthermore, the compound (A) may contain a tertiary nitrogen atom in addition to the primary nitrogen atom and the secondary nitrogen atom.

In the present disclosure, the term “primary nitrogen atom” refers to a nitrogen atom bonded exclusively to two hydrogen atoms and one non-hydrogen atom (e.g., a nitrogen atom contained a primary amino group (—NH₂ group)) or a nitrogen atom bonded exclusively to three hydrogen atoms and one non-hydrogen atom (a cation).

The term “secondary nitrogen atom” refers to a nitrogen atom bonded exclusively to one hydrogen atom and two non-hydrogen atoms (i.e., a nitrogen atom contained in a functional group represented by the following Formula (a)) or a nitrogen atom bonded exclusively to two hydrogen atoms and two non-hydrogen atoms (a cation).

The term “tertiary nitrogen atom” refers to a nitrogen atom bonded exclusively to three non-hydrogen atoms (i.e., a nitrogen atom that is a functional group represented by the following Formula (b)) or a nitrogen atom bonded exclusively to one hydrogen atom and three non-hydrogen atoms (a cation).

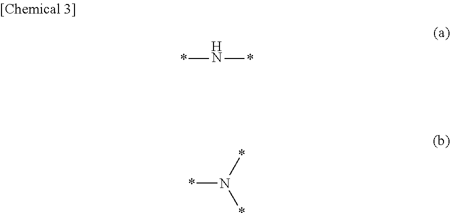

In Formulas (a) and (b), * indicates a bonding position with a non-hydrogen atom.

Here, the functional group represented by Formula (a) may be a functional group constituting a part of a secondary amino group (—NHR^{a} group; Ra represents an alkyl group) or may be a divalent linking group contained in the skeleton of a polymer.

The functional group represented by Formula (b) (i.e., a tertiary nitrogen atom) may be a functional group constituting a part of a tertiary amino group (—NR^{b}R^{c} group; R^{b} and R^{c} each independently represent an alkyl group) or may be a trivalent linking group contained in the skeleton of a polymer.

The weight average molecular weight of the compound (A) is from 90 to 400,000. Examples of the compound (A) include aliphatic amines, compounds having a siloxane bond (Si—O bond) and an amino group, and amine compounds having a ring structure but no Si—O bond in the molecule. When the compound (A) is an aliphatic amine, the weight average molecular weight is preferably from 10,000 to 200,000. In a case in which the compound (A) is a compound having a siloxane bond (Si—O bond) and an amino group, the weight average molecular weight is preferably from 130 to 10,000, more preferably from 130 to 5,000, and still more preferably from 130 to 2,000. In a case in which the compound (A) is an amine compound having a ring structure but no Si—O bond in the molecule, the weight average molecular weight is preferably from 90 to 600.

In the present disclosure, the weight average molecular weight refers to a weight average molecular weight in terms of polyethylene glycol, measured by gel permeation chromatography (GPC) for a substance other than the monomer.

Specifically, the weight average molecular weight is calculated using an aqueous solution of sodium nitrate with a concentration of 0.1 mol/L as a developing solvent, detecting the refractive index at a flow rate of 1.0 mL/min using an analytical device, SHODEX DET RI-101, and two types of analytical columns (TSKGEL G6000PWXL-CP and TSKGEL G3000PWXL-CP manufactured by Tosoh Corporation), and calculating with analytical software (Empower3 manufactured by Waters) using polyethylene glycol/polyethylene oxide as standards.

Furthermore, the compound (A) may further have an anionic functional group, a nonionic functional group, or the like, if necessary.

The nonionic functional group may be a hydrogen-bond-accepting group or a hydrogen-bond-donating group. Examples of the nonionic functional group may include a hydroxy group, a carbonyl group, and an ether group (—O—).

The anionic functional group is not particularly limited as long as it is a functional group that can bear a negative charge. Examples of the anionic functional group may include a carboxylic acid group, a sulfonic acid group, and a sulfate group.

Examples of the compound (A) include aliphatic amines. More specific examples thereof include: polyalkyleneimines, which are polymers of alkyleneimines such as ethyleneimine, propyleneimine, butyleneimine, pentyleneimine, hexyleneimine, heptyleneimine, octyleneimine, trimethyleneimine, tetramethyleneimine, pentamethyleneimine, hexamethyleneimine, and octamethyleneimine; polyallylamines; and polyacrylamides.

Polyethyleneimine (PEI) can be produced by known methods described in Japanese Patent Publication (JP-B) No. S43-8828, JP-B No. S49-33120, Japanese Patent Application Laid-Open (JP-A) No. 2001-213958, International Publication No. 2010/137711, and other literature. Polyalkyleneimines other than polyethyleneimine can also be produced by the same method as for polyethyleneimine.

It is also preferable that the compound (A) is a derivative of the above-described poly alkyleneimine (a poly alkyleneimine derivative; particularly preferably a polyethyleneimine derivative). The polyalkyleneimine derivative is not particularly limited as long as it is a compound which can be produced using the above polyalkyleneimine. Specific examples of the polyalkyleneimine include: polyalkyleneimine derivatives obtained by introducing an alkyl group (preferably an alkyl group having from 1 to 10 carbon atoms), an aryl group, or the like into a polyalkyleneimine; and polyalkyleneimine derivatives obtained by introducing a crosslinkable group such as a hydroxyl group into a polyalkyleneimine.

These polyalkyleneimine derivatives can be produced by a method commonly used using the above polyalkyleneimines. Specifically, it can be produced in accordance with the method described in, for example, JP-A No. H6-016809.

As the polyalkyleneimine derivative, a highly branched polyalkyleneimine obtained by reacting a polyalkyleneimine with a monomer containing a cationic functional group to increase the branching degree of the polyalkyleneimine is also preferable.

Examples of a method of obtaining a highly branched polyalkyleneimine include: a method in which a polyalkyleneimine having a plurality of secondary nitrogen atoms in the skeleton is reacted with a cationic functional group-containing monomer, and at least one of the plurality of secondary nitrogen atoms is substituted with the cationic functional group-containing monomer; and a method in which a polyalkyleneimine having a plurality of terminal primary nitrogen atoms is reacted with a cationic functional group-containing monomer, and at least one of the plurality of primary nitrogen atoms is substituted with the cationic functional group-containing monomer.

Examples of a cationic functional group that is introduced for increasing the branching degree may include an aminoethyl group, an aminopropyl group, a diaminopropyl group, an aminobutyl group, a diaminobutyl group, and triaminobutyl group. However, from the viewpoints of decreasing the cationic functional group equivalent and increasing the cationic functional group density, an aminoethyl group is preferable.

Moreover, the polyethyleneimine and derivatives thereof may be commercially available products. For example, polyethyleneimines and derivatives thereof commercially available from NIPPON SHOKUBAI CO., LTD., BASF, MP-Biomedicals, and the like may be selected and used, if appropriate.

Examples of the compound (A) include the above-described aliphatic amines as well as compounds having an Si—O bond and an amino group. Examples of compounds having an Si—O bond and an amino group include a siloxane diamine, a silane coupling agent having an amino group, and a siloxane polymer of a silane coupling agent having an amino group.

Examples of the silane coupling agent having an amino group include a compound represented by the following Formula (A-3).

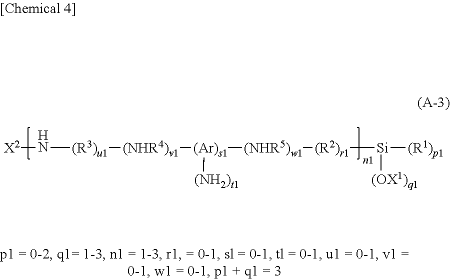

In Formula (A-3), R¹ represents an optionally substituted alkyl group having from 1 to 4 carbon atoms. R² and R³ each independently represent an optionally substituted alkylene group having from 1 to 12 carbon atoms (which may contain a carbonyl group, an ether group, or the like in the skeleton), an ether group, or a carbonyl group. R⁴ and R⁵ each independently represent an optionally substituted alkylene group having from 1 to 4 carbon atoms or a single bond. Ar represents a divalent or trivalent aromatic ring. X¹ represents hydrogen or an optionally substituted alkyl group having from 1 to 5 carbon atoms. X² represents hydrogen, a cycloalkyl group, a heterocyclic group, an aryl group, or an optionally substituted alkyl group having from 1 to 5 carbon atoms (which may contain a carbonyl group, an ether group, or the like in the skeleton). A plurality of R¹, R², R³, R⁴, R⁵ and X¹ may be the same as or different from each other.

Substituents of the alkyl group and alkylene group in R¹, R², R³, R⁴, R⁵, X¹, and X² each independently include an amino group, a hydroxy group, an alkoxy group, a cyano group, a carboxylic acid group, a sulfonic acid group, a halogen, and the like.

The divalent or trivalent aromatic ring for Ar is, for example, a divalent or trivalent benzene ring. Examples of the aryl group in X² include a phenyl group, a methylbenzyl group, and a vinylbenzyl group.

Specific examples of the silane coupling agent represented by Formula (A-3) include N-(2-aminoethyl)-3-aminopropylmethyldiethoxysilane, N-(2-aminoethyl)-3-aminopropyltriethoxysilane, N-(2-aminoethyl)-3-aminoisobutyldimethylmethoxysilane, N-(2-aminoethyl)-3-aminoisobutylmethyldimethoxysilane, N-(2-aminoethyl)-11-aminoundeciltrimethoxysilane, 3-aminopropyltrimethoxysilane, 3-aminopropyltriethoxysilane, N-phenyl-3-aminopropyltrimethoxysilane, (aminoethylaminoethyl)phenyltriethoxysilane, methylbenzylaminoethylaminopropyltrimethoxysilane, benzylaminoethylaminopropyltriethoxysilane, 3-ureidopropyltriethoxysilane, (aminoethylaminoethyl)phenethyltrimethoxysilane, (aminoethylaminomethyl)phenethyltrimethoxysilane, N-[2-[3-(trimethoxysilyl)propylamino]ethyl]ethylenediamine, 3-aminopropyldiethoxymethylsilane, 3-aminopropyldimethoxymethylsilane, 3-aminopropyldimethylethoxysilane, 3-aminopropyldimethylmethoxysilane, trimethoxy[2-(2-aminoethyl)-3-aminopropyl]silane, diaminomethylmethyldiethoxysilane, methylaminomethylmethyldiethoxysilane, p-aminophenyltrimethoxysilane, N-methylaminopropyltriethoxysilane, N-methylaminopropylmethyldiethoxysilane, (phenylaminomethyl)methyldiethoxysilane, acetamidepropyltrimethoxysilane, and hydrolysates thereof.

Examples of a silane coupling agent containing an amino group other than those represented by Formula (A-3) include N,N-bis[3-(trimethoxysilyl)propyl]ethylenediamine, N,N′-bis[3-(trimethoxysilyl)propyl]ethylenediamine, bis[(3-triethoxysilyl)propyl]amine, piperazinylpropylmethyldimethoxysilane, bis[3-(triethoxysilyl)propyl]urea, bis(methyldiethoxysilylpropyl)amine, 2,2-dimethoxy-1,6-diaza-2-silacyclooctane, 3,5-diamino-N-(4-(methoxydimethylsilyl)phenyl)benzamide, 3,5-diamino-N-(4-(triethoxysilyl)phenyl)benzamide, 5-(ethoxydimethylsilyl)benzene-1,3-diamine, and hydrolysates thereof.

The above-described silane coupling agent having an amino group may be used singly, or in combination of two or more kinds thereof. A combination of the silane coupling agent having an amino group and a silane coupling agent having no amino group may also be used. For example, a silane coupling agent having a mercapto group may be used for improving adhesion to metals.

Polymers (siloxane polymers) formed from these silane coupling agents via a siloxane bond (Si—O—Si) may also be used. For example, a polymer having a linear siloxane structure, a polymer having a branched siloxane structure, a polymer having a cyclic siloxane structure, a polymer having a cage-like siloxane structure, and the like can be obtained from hydrolysates of 3-aminopropyltrimethoxysilane. The cage-like siloxane structure is represented by, for example, the following Formula (A-1).

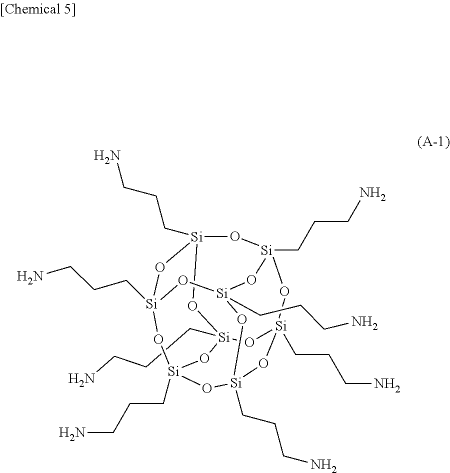 [SMILES: NCCC[Si]12O[Si]3(CCCN)O[Si]4(CCCN)O[Si](CCCN)(O1)O[Si]1(CCCN)O[Si](CCCN)(O2)O[Si](CCCN)(O3)O[Si](CCCN)(O4)O1]

Examples of siloxane diamine include a compound represented by the following Formula (A-2). In Formula (A-2), i is an integer from 0 to 4, j is an integer from 1 to 3, and Me is a methyl group.

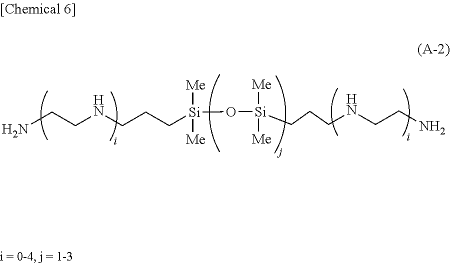

In addition, examples of siloxane diamine include 1,3-bis(3-aminopropyl)tetramethyldisiloxane (i=0 and j=1 in Formula (A-2)) and 1,3-bis(2-aminoethylamino)propyltetramethyldisiloxane (i=1 and j=1 in Formula (A-2)).

Examples of the compound (A) include the above-described aliphatic amines and compounds having an Si—O bond and an amino group as well as amine compounds having a ring structure but no Si—O bond in the molecule. Among these, amine compounds having a ring structure and a weight average molecular weight of from 90 to 600 but no Si—O bond in the molecule are preferable. Examples of amine compounds having a ring structure and a weight average molecular weight of from 90 to 600 but no Si—O bond in the molecule include alicyclic amines, aromatic amines, and heterocyclic amines. The molecule may have a plurality of ring structures in the molecule, and the plurality of ring structures may be the same as or different from each other. As the amine compound having a ring structure, a compound having an aromatic ring is more preferable since a more thermally stable compound can be easily obtained.

As the amine compound having a ring structure and a weight average molecular weight of from 90 to 600 but no Si—O bond in the molecule, a compound having a primary amino group is preferable since it is easy to form a thermally crosslinked structure such as amide, amide-imide, or imide together with the crosslinking agent (B), thereby allowing further enhancing heat resistance. As the above-described amine compound, a diamine compound having two primary amino groups, a triamine compound having three primary amino groups, or the like is preferable since it is easy to increase the number of thermally crosslinked structures such as amide, amide-imide, and imide together with the crosslinking agent (B), thereby allowing further enhancing heat resistance.

Examples of alicyclic amines include cyclohexylamine and dimethylaminocyclohexane.

Examples of alicyclic amines include diaminodiphenyl ether, xylylene diamine (preferably paraxylylene diamine), diaminobenzene, diaminotoluene, methylene dianiline, dimethyldiaminobiphenyl, bis(trifluoromethyl)diaminobiphenyl, diaminobenzophenone, diaminobenzanilide, bis(aminophenyl)fluorene, bis(aminophenoxy)benzene, bis(aminophenoxy)biphenyl, dicarboxydiaminodiphenylmethane, diaminoresorcinol, dihydroxybenzidine, diaminobenzidine, 1,3,5-triaminophenoxybenzene, 2,2′-dimethylbenzidine, tris(4-aminophenyl)amine, 2,7-diaminofluorene, 1,9-diaminofluorene, and dibenzylamine.

Examples of heterocyclic amines include heterocycles containing a sulfur atom as a heteroatom (e.g., a thiophene ring) and heterocycles containing a nitrogen atom as a heteroatom (e.g., five-membered rings such as a pyrrole ring, a pyrrolidine ring, a pyrazole ring, an imidazole ring, and a triazole ring; six-membered rings such as an isocyanuric ring, a pyridine ring, a pyridazine ring, a pyrimidine ring, a pyrazine ring, a piperidine ring, a piperazine ring, and a triazine ring; condensed rings such as an indole ring, an indoline ring, a quinoline ring, an acridine ring, a naphthyridine ring, a quinazoline ring, a purine ring, and a quinoxaline ring).

Examples of heterocyclic amines having a nitrogen-containing heterocycle include melamine, ammeline, melam, melem, and tris(4-aminophenyl)amine.

Furthermore, examples of an amine compound having both a heterocycle and an aromatic ring include N2,N4,N6-tris(4-aminophenyl)-1,3,5-triazine-2,4,6-triamine.

As the compound (A) has a primary or secondary amino group, it allows the substrates to be strongly bonded to each other by electrostatic interaction with a functional group such as a hydroxyl group, an epoxy group, a carboxy group, an amino group, or a mercapto group which may be present on the surfaces of the first and second substrates or by forming a tight covalent bond with the functional group.

As the compound (A) has a primary or secondary amino group, it is easily soluble in the polar solvent (D) described below. By using the compound (A) that is easily soluble in the polar solvent (D), the affinity with the hydrophilic surface of a substrate such as a silicon substrate is increased, making it easier to form a smooth film and allowing the thicknesses of the first resin layer and the second resin layer to be reduced.

As the compound (A), from the viewpoint of forming a smooth thin film, an aliphatic amine or a compound having an Si—O bond and an amino group is preferable, and from the viewpoint of heat resistance, a compound having an Si—O bond and an amino group is more preferable.

In a case in which the compound (A) contains a compound having an Si—O bond and an amino group, it is preferable from the viewpoint of forming a smooth thin film that the ratio of the total number of primary nitrogen atoms and secondary nitrogen atoms to the number of silicon atoms in the compound (A) (total number of primary nitrogen atoms and secondary nitrogen atoms/number of silicon atoms) is from 0.2 to 5.

In a case in which the compound (A) contains a compound having an Si—O bond and an amino group, from the viewpoint of adhesion between substrates, it is preferable that a non-crosslinkable group such as a methyl group bonded to Si satisfies the relationship of (non-crosslinkable group)/Si<2 in terms of molar ratio in the compound having a Si—O bond and an amino group. It is presumed that by satisfying this relationship, the crosslinking density (crosslinking between Si—O—Si bonds and amide bonds, imide bonds, or the like) of the formed film is improved, the substrates have sufficient adhesive strength, and peeling of the substrates can be suppressed.

As described above, the compound (A) has a cationic functional group containing at least one of a primary nitrogen atom or a secondary nitrogen atom. Here, in a case in which the compound (A) contains a primary nitrogen atom, the proportion of primary nitrogen atoms in the total nitrogen atoms in the compound (A) is preferably 20% by mole or more, more preferably 25% by mole or more, and still more preferably 30% by mole or more. In addition, the compound (A) may have a cationic functional group that contains a primary nitrogen atom and does not contain any nitrogen atom other than a primary nitrogen atom (for example, a secondary nitrogen atom or a tertiary nitrogen atom).

Here, in a case in which the compound (A) contains a secondary nitrogen atom, the proportion of secondary nitrogen atoms in the total nitrogen atoms in the compound (A) is preferably from 5% by mole to 50% by mole and more preferably from 10% by mole to 45% by mole.

Moreover, the compound (A) may contain a tertiary nitrogen atom as well as a primary nitrogen atom and a secondary nitrogen atom. In a case in which the compound (A) contains a tertiary nitrogen atom, the proportion of tertiary nitrogen atoms in the total nitrogen atoms in the compound (A) is from 20% by mole to 50% by mole and more preferably from 25% by mole to 45% by mole.

In the present disclosure, the content of components derived from the compound (A) in the first resin layer or the second resin layer is not particularly limited. For example, the content in the entire first resin layer or the entire second resin layer can be from 1% by mass to 82% by mass, and is preferably from 5% by mass to 82% by mass and more preferably from 13% by mass to 82% by mass.

### (Crosslinking Agent (B))

The crosslinking agent (B) is a compound having three or more —C(═O)OX groups (X is a hydrogen atom or an alkyl group having from 1 to 6 carbon atoms) in the molecule, in which of the three or more —C(═O)OX groups (hereinafter also referred to as “COOX”), one to six are —C(═O)OH groups (hereinafter also referred to as “COOH”), and a weight average molecular weight of from 200 to 2000.

The crosslinking agent (B) is a compound having three or more —C(═O)OX groups (X is a hydrogen atom or an alkyl group having from 1 to 6 carbon atoms) in the molecule, and is preferably a compound having three to six —C(═O)OX groups in the molecule, and more preferably a compound having three or four —C(═O)OX groups in the molecule.

In the crosslinking agent (B), X in the —C(═O)OX group may be a hydrogen atom or an alkyl group having from 1 to 6 carbon atoms, and among these, a hydrogen atom, a methyl group, an ethyl group, and a propyl group are preferable. X in the —C(═O)OX group may be the same as or different from each other.

The crosslinking agent (B) is a compound having one to six —C(═O)OH groups, in which X is a hydrogen atom, in the molecule, and is preferably a compound having one to four —C(═O)OH groups in the molecule, more preferably a compound having two to four —C(═O)OH groups in the molecule, and still more preferably a compound having two or three —C(═O)OH groups in the molecule.

The crosslinking agent (B) is a compound having a weight average molecular weight of from 200 to 2000. The weight average molecular weight of the crosslinking agent (B) is preferably from 200 to 1000, more preferably from 200 to 600, and still more preferably from 200 to 400.

The crosslinking agent (B) preferably has a ring structure in the molecule. Examples of the ring structure include an alicyclic structure and an aromatic ring structure. In addition, the crosslinking agent (B) may have a plurality of ring structures in the molecule, and the plurality of ring structures may be the same as or different from each other.

Examples of the alicyclic structure include alicyclic structures having from 3 to 8 carbon atoms and preferably alicyclic structures having from 4 to 6 carbon atoms. The ring structure may be saturated or unsaturated. More specific examples of the alicyclic structure include: saturated alicyclic structures such as a cyclopropane ring, a cyclobutane ring, a cyclopentane ring, a cyclohexane ring, a cycloheptane ring, and a cyclooctane ring; and unsaturated alicyclic structures such as a cyclopropene ring, a cyclobutene ring, a cyclopentene ring, a cyclohexene ring, a cycloheptene ring, and a cyclooctene ring.

The aromatic ring structure is not particularly limited as long as it is a ring structure that exhibits aromaticity. Examples thereof include: benzene-based aromatic rings such as a benzene ring, a naphthalene ring, an anthracene ring, and a perylene ring; aromatic heterocycles such as a pyridine ring and a thiophene ring; and non-benzene-based aromatic rings such as indene ring, azulene ring, and other.

The ring structure that the crosslinking agent (B) has in the molecule is preferably at least one selected from the group consisting of a cyclobutane ring, a cyclopentane ring, a cyclohexane ring, a benzene ring, and a naphthalene ring. From the viewpoint of further increasing the heat resistance of the first resin layer and the second resin layer, at least one of a benzene ring or a naphthalene ring is more preferable.

As described above, the crosslinking agent (B) may have a plurality of ring structures in the molecule. In a case in which the ring structure is benzene, the crosslinking agent (B) may have a biphenyl structure, a benzophenone structure, a diphenyl ether structure, or the like.

The crosslinking agent (B) preferably has a fluorine atom in the molecule, more preferably has from 1 to 6 fluorine atoms in the molecule, and still more preferably has from 3 to 6 fluorine atoms in the molecule. For example, the crosslinking agent (B) may have a fluoroalkyl group in the molecule, specifically, a trifluoroalkyl group or a hexafluoroisopropyl group.

Furthermore, examples of the crosslinking agent (B) include a carboxylic acid compound such as alicyclic carboxylic acid, benzene carboxylic acid, naphthalene carboxylic acid, diphthalic acid, or fluorinated aromatic carboxylic acid; and a carboxylic acid ester compound such as alicyclic carboxylic acid ester, benzene carboxylic acid ester, naphthalene carboxylic acid ester, diphthalic acid ester, or fluorinated aromatic carboxylic acid ester. The carboxylic acid ester compound is a compound having a carboxy group (—C(═O)OH group) in the molecule, in which of three or more —C(═O)OX groups, at least one X is an alkyl group having from 1 to 6 carbon atoms (i.e., having an ester bond). In the present disclosure, as the crosslinking agent (B) is a carboxylic acid ester compound, aggregation due to association between the compound (A) and the crosslinking agent (B) is suppressed, resulting in fewer aggregates and pits, and facilitating adjustment of the film thickness.

The carboxylic acid compound is preferably a tetravalent or less carboxylic acid compound having four or less —C(═O)OH groups, and more preferably a trivalent or tetravalent carboxylic acid compound having three or four —C(═O)OH groups.

The carboxylic acid ester compound is a compound containing three or less carboxy groups (—C(═O)OH group) and three or less ester bonds in the molecule, and more preferably a compound having two or less carboxy groups and two or less ester bonds in the molecule.

In addition, in the carboxylic acid ester compound, in a case in which X is an alkyl group having from 1 to 6 carbon atoms in three or more —C(═O)OX groups, X is preferably a methyl group, an ethyl group, a propyl group, or a butyl group. However, from the viewpoint of further suppressing aggregation due to association between the compound (A) and the crosslinking agent (B), an ethyl group or a propyl group is preferable.

Specific examples of the carboxylic acid compound include, but are not limited to: alicyclic carboxylic acids such as 1,2,3,4-cyclobutanetetracarboxylic acid, 1,2,3,4-cyclopentanetetracarboxylic acid, 1,3,5-cyclohexanetricarboxylic acid, 1,2,4-cyclohexanetricarboxylic acid, 1,2,4,5-cyclohexanetetracarboxylic acid, and 1,2,3,4,5,6-cyclohexanehexacarboxylic acid; benzene carboxylic acids such as 1,2,4-benzenetricarboxylic acid, 1,3,5-benzenetricarboxylic acid, pyromellitic acid, 3,4′-biphthalic acid, p-phenylenebis(trimellitate acid), benzenepentacarboxylic acid, and mellitic acid; naphthalene carboxylic acids such as 1,4,5,8-naphthalene tetracarboxylic acid and 2,3,6,7-naphthalene tetracarboxylic acid; diphthalic acids such as 3,3′,5,5′-tetracarboxydiphenylmethane, biphenyl-3,3′,5,5′-tetracarboxylic acid, biphenyl-3,4′,5-tricarboxylic acid, biphenyl-3,3′,4,4′-tetracarboxylic acid, benzophenone-3,3′,4,4′-tetracarboxylic acid, 4,4′-oxydiphthalic acid, 3,4′-oxydiphthalic acid, 1,3-bis(phthalic acid)tetramethyldisiloxane, 4,4′-(ethyne-1,2-diyl)diphthalic acid), 4,4′-(1,4-phenylenebis(oxy))diphthalic acid), 4,4′-([1,1′-biphenyl]-4,4′-diylbis(oxy))diphthalic acid), and 4,4′-((oxybis(4,1-phenylene))bis(oxy))diphthalic acid); perylene carboxylic acids such as perylene-3,4,9,10-tetracarboxylic acid; anthracene carboxylic acids such as anthracene-2,3,6,7-tetracarboxylic acid; fluorinated aromatic carboxylic acids such as 4,4′-(hexafluoroisopropylidene)diphthalic acid, 9,9-bis(trifluoromethyl)-9H-xanthene-2,3,6,7-tetracarboxylic acid, and 1,4-ditrifluoromethylpyromellitic acid.

Specific examples of the carboxylic acid ester compound include a compound in which at least one carboxy group in the specific examples of the carboxylic acid compound described above is substituted with an ester group. Examples of the carboxylic acid ester compound include half-esterified compounds represented by the following Formulas (B-1) to (B-5).

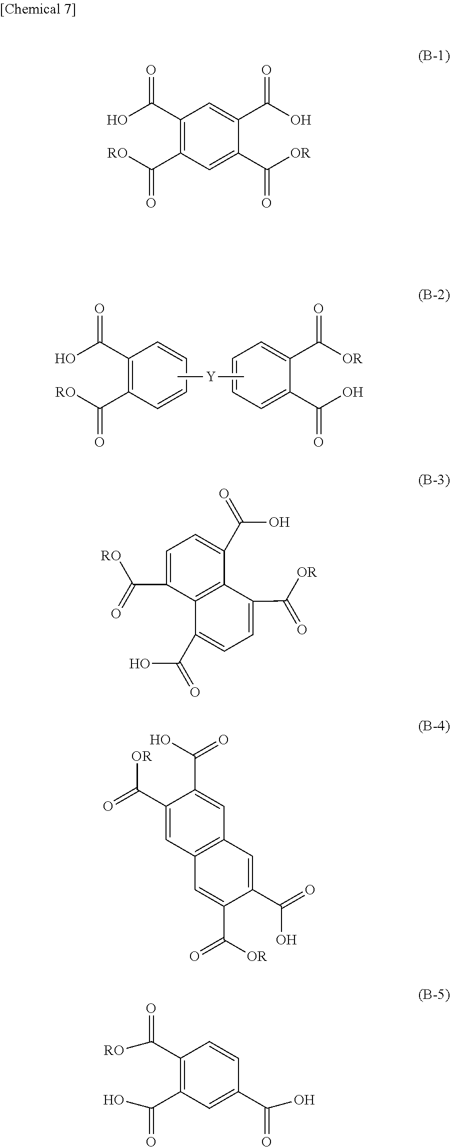

In Formulas (B-1) to (B-5), R is each independently an alkyl group having from 1 to 6 carbon atoms. Among them, a methyl group, an ethyl group, a propyl group, and a butyl group are preferable, and an ethyl group and a propyl group are more preferable.

In Formula (B-2), Y is a single bond, O, C═O, or C(CF₃)₂.

The half-esterified compounds can be produced, for example, by mixing a carboxylic acid anhydride, which is an anhydride of the above-described carboxylic acid compound, with an alcohol solvent and ring-opening the carboxylic acid anhydride.

In the present disclosure, the contents of components derived from the crosslinking agent (B) in the first resin layer and the second resin layer are not particularly limited. For example, the ratio of the number of carbonyl groups (—(C═O)—Y) in a substance derived from the crosslinking agent (B) to the number of all nitrogen atoms in a substance derived from the compound (A) ((—(C═O)—Y)/N) is independently preferably from 0.1 to 3.0, more preferably from 0.3 to 2.5, and still more preferably from 0.4 to 2.2. Here, in —(C═O)—Y, Y represents an imide- or amide-crosslinked nitrogen atom, OH, or an ester group. As long as (—(C═O)—Y)/N is from 0.1 to 3.0, the first resin layer and the second resin layer preferably have a crosslinked structure such as amide, amide-imide, or imide, and are more excellent in heat resistance.

### (Polar Solvent (D))

In the step A, a resin composition containing a resin material may be applied to the surface of at least one of the first substrate or the second substrate. At this time, the resin composition containing a resin material contains preferably a polar solvent (D) as well as resin materials such as the above-described compound (A) and crosslinking agent (B). The polar solvent (D) refers herein to a solvent having a relative dielectric constant of 5 or more at room temperature. Specific examples of the polar solvent (D) include: protic inorganic compounds such as water and heavy water; alcohols such as methanol, ethanol, 1-propanol, 2-propanol, 1-butanol, 2-butanol, isobutyl alcohol, isopentyl alcohol, cyclohexanol, ethylene glycol, propylene glycol, 2-methoxyethanol, 2-ethoxyethanol, benzyl alcohol, diethylene glycol, triethylene glycol, and glycerin; ethers such as tetrahydrofuran and dimethoxyethane; aldehydes/ketones such as furfural, acetone, ethyl methyl ketone, and cyclohexane; acid derivatives such as acetic anhydride, ethyl acetate, butyl acetate, ethylene carbonate, propylene carbonate, formaldehyde, N-methylformamide, N,N-dimethylformamide, N-methylacetamide, N,N-dimethylacetamide, N-methyl-2-pyrrolidone, and hexamethylphosphoramide; nitriles such as acetonitrile and propionitrile; nitro compounds such as nitromethane and nitrobenzene; and sulfur compounds such as dimethyl sulfoxide. The polar solvent (D) contains preferably a protic solvent, more preferably water, and still more preferably ultrapure water.

The content of the polar solvent (D) in the resin composition is not particularly limited, and is, for example, from 1.0% by mass to 99.99896% by mass, and preferably from 40% by mass to 99.99896% by mass with respect to the entire resin composition.

The boiling point of the polar solvent (D) is preferably 150° C. or less and more preferably 120° C. or less from the viewpoint of volatilizing the polar solvent (D) by heating when forming the first resin layer and the second resin layer, thereby reducing the amount of the residual solvent in the first resin layer and the second resin layer.

### (Additive (C))

The resin composition containing a resin material may contain an additive (C) as well as the above-described resin materials including the compound (A) and the crosslinking agent (B), the polar solvent (D), and the like. Examples of the additive (C) include an acid (C-1) having a carboxy group and a weight average molecular weight of from 46 to 195 and a base (C-2) having a nitrogen atom and a weight average molecular weight of from 17 to 120 without a ring structure. Although the additive (C) volatilizes due to heating when forming the first resin layer and the second resin layer, the first resin layer and the second resin layer in the substrate layered body of the present disclosure may contain the additive (C).

The acid (C-1) is an acid having a carboxy group and a weight average molecular weight of from 46 to 195. It is presumed that the acid (C-1) is contained as the additive (C), and thus an ionic bond is formed between the amino group in the compound (A) and the carboxy group in the acid (C-1), thereby suppressing aggregation due to association between the compound (A) and the crosslinking agent (B). More specifically, it is presumed that the aggregation is suppressed because the interaction (e.g., electrostatic interaction) between the ammonium ion derived from the amino group in the compound (A) and the carboxylate ion derived from the carboxy group in the acid (C-1) is stronger than the interaction between the ammonium ion derived from the amino group in the compound (A) and the carboxylate ion derived from the carboxy group in the crosslinking agent (B). However, the present invention is not limited in any way by the above presumption.

The acid (C-1) is not particularly limited as long as it is a compound having a carboxy group and a weight average molecular weight of from 46 to 195, and examples of the acid (C-1) include monocarboxylic acid compounds, dicarboxylic acid compounds, and oxydicarboxylic acid compounds. More specific examples of the acid (C-1) include formic acid, acetic acid, malonic acid, oxalic acid, citric acid, benzoic acid, lactic acid, glycolic acid, glyceric acid, butyric acid, methoxyacetic acid, ethoxyacetic acid, phthalic acid, terephthalic acid, picolinic acid, salicylic acid, and 3,4,5-trihydroxybenzoic acid.

In the present disclosure, the content of the acid (C-1) in the resin composition containing a resin material is not particularly limited. For example, the ratio (COOH/N) of the number of carboxy groups in the acid (C-1) to the total number of nitrogen atoms in the compound (A) is preferably from 0.01 to 10, more preferably from 0.02 to 6, and still more preferably from 0.5 to 3.

The base (C-2) is a base having a nitrogen atom and a weight average molecular weight of from 17 to 120. It is presumed that the resin composition containing a resin material contains the base (C-2) as the additive (C), and thus an ionic bond is formed between a carboxy group in the crosslinking agent (B) and an amino group in the base (C-2), thereby suppressing aggregation due to association between the compound (A) and the crosslinking agent (B). More specifically, it is presumed that the aggregation is suppressed because the interaction between the carboxylate ion derived from the carboxy group in the crosslinking agent (B) and the ammonium ion derived from the amino group in the base (C-2) is stronger than the interaction between the ammonium ion derived from the amino group in the compound (A) and the carboxylate ion derived from the carboxy group in the crosslinking agent (B). However, the present invention is not limited in any way by the above presumption.

The base (C-2) is not particularly limited as long as it is a compound having a nitrogen atom and a weight average molecular weight of from 17 to 120 without a ring structure, and examples of the base include monoamine compounds and diamine compounds. More specifically, examples of the base (C-2) include ammonia, ethylamine, ethanolamine, diethylamine, triethylamine, ethylenediamine, N-acetylethylenediamine, N-(2-aminoethyl)ethanolamine, and N-(2-aminoethyl)glycine.

In the present disclosure, the content of the base (C-2) in the resin composition containing a resin material is not particularly limited, and for example, the ratio (N/COOH) of the number of nitrogen atoms in the base (C-2) to the number of carboxy groups in the crosslinking agent (B) is preferably from 0.5 to 5 and more preferably from 0.9 to 3.

In a case in which the first resin layer and the second resin layer of the substrate layered body of the present disclosure are required to have insulating properties, tetraethoxysilane, tetramethoxysilane, bistriethoxysilylethane, bistriethoxysilylmethane, bis(methyldiethoxysilyl)ethane, 1,1,3,3,5,5-hexaethoxy-1,3,5-trisilacyclohexane, 1,3,5,7-tetramethyl-1,3,5,7-tetrahydroxylcyclosiloxane, 1,1,4,4-tetramethyl-1,4-diethoxydisilethylene, or 1,3,5-trimethyl-1,3,5-trimethyl-1,3,5-triethoxy-1,3,5-trisilacyclohexane may be mixed therewith in order to improve insulation or mechanical strength. Furthermore, methyltriethoxysilane, dimethyldiethoxysilane, trimethylethoxysilane, or the like may be mixed therewith in order to improve the hydrophobicity of the first resin layer and the second resin layer having insulating properties. These compounds may be mixed so as to control etch selectivity.

The resin composition containing a resin material may contain a solvent other than the polar solvent (D), and an example of the solvent is normal hexane.

In addition, the resin composition containing a resin material may contain phthalic acid, benzoic acid, or a derivative thereof, for example, in order to improve electrical characteristics.

The resin composition containing a resin material may contain benzotriazole or a derivative thereof, for example, in order to inhibit corrosion of copper.

The pH of the resin composition containing a resin material is not particularly limited, and is preferably from 2.0 to 12.0.

In a case in which the acid (C-1) is used as the additive (C), it is preferable to mix a mixture of the acid (C-1) and the compound (A) with the crosslinking agent (B). In other words, it is preferable to premix the compound (A) with the acid (C-1) before mixing the compound (A) with the crosslinking agent (B). This makes it possible to suppress clouding and gelation of the resin composition containing a resin material (gelation may undesirably cause the resin composition to take a long time to become transparent) in a preferred manner when the compound (A) and the crosslinking agent (B) are mixed.

In a case in which the base (C-2) is used as the additive (C), it is preferable to mix a mixture of the base (C-2) and the crosslinking agent (B) with the compound (A). In other words, it is preferable to premix the crosslinking agent (B) with the base (C-2) before mixing the compound (A) with the crosslinking agent (B). This makes it possible to suppress clouding and gelation of the resin composition containing a resin material (gelation may undesirably cause the resin composition to take a long time to become transparent) in a preferred manner when the compound (A) and the crosslinking agent (B) are mixed.

Examples of a method of applying a resin material to the surface of at least one of the first substrate or the second substrate include vapor phase film formation methods such as deposition polymerization, chemical vapor deposition (CVD), and atomic layer deposition (ALD), and coating methods such as dipping, spraying, spin coating, and bar coating. In the case of applying a resin material by a coating method, it is preferable to apply the above-described resin composition containing a resin material. For example, in the case of forming a film having a thickness on the order of microns, it is preferable to use a bar coating method, and in the case of forming a film having a thickness on the order of nanometers (several nanometers to several hundred nanometers (nm)), it is preferable to use a spin coating method. The thickness of the resin material may be adjusted as appropriate depending on the intended thickness of the first resin layer and the second resin layer.

For example, a method of applying a resin material by spin coating is not particularly limited. For example, a method can be used in which a resin composition containing a resin material is dropped onto the surface of the first substrate while rotating the first substrate with a spin coater, and then the rotation speed of the first substrate is increased to dry the resin composition.

Regarding a method of applying a resin material by spin coating, there are no particular limitations on the conditions such as the rotation speed of the substrate, the amount and time of dropping of the resin composition containing a resin material, and the rotation speed of the substrate during drying, and these may be adjusted taking into consideration the thickness of the resin material to be formed and the like, if appropriate.

To remove excess resin material from the substrate to which the resin material has been applied, the substrate to which the resin material has been applied may be cleaned. Examples of a cleaning method include wet cleaning using a rinsing liquid such as a polar solvent, and plasma cleaning.

In the method of producing a substrate layered body of the present disclosure, the step A may include a step of forming a first resin layer and a second resin layer by curing a resin material applied to one surface of a first substrate and one surface of a second substrate. For example, the resin material is cured by heating or the like, thereby forming a first resin layer and a second resin layer. At this time, in a case in which the resin material contains a thermosetting compound, the resin material is cured by heating it to a temperature equal to or higher than the curing temperature.

It is preferable that the resin material applied to one surface of the first substrate and one surface of the second substrate is heated at from 100° C. to 450° C. so as to be cured.

The above-described temperatures refer to the surface temperature of the resin material applied to the surface.

By heating the resin material, the solvent in the resin composition containing a resin material is removed. In addition, a cured product is obtained as a result of reacting the components in the resin material, thereby forming the first resin layer and the second resin layer each containing the cured product.

From the viewpoint of suppressing thermal damage to devices such as semiconductor memories, the temperature is preferably from 150° C. to 450° C., more preferably from 180° C. to 400° C., still more preferably from 180° C. to 250° C., and particularly preferably from 180° C. to 200° C.

There is no particular limitation on the pressure when the resin material applied to the surface is heated, but an absolute pressure of from more than 17 Pa to atmospheric pressure is preferable.

The absolute pressure is more preferably from 1,000 Pa to atmospheric pressure, still more preferably from 5,000 Pa to atmospheric pressure, and particularly preferably from 10,000 Pa to atmospheric pressure.

The resin material applied to the surface can be heated by an ordinary method using a furnace or a hot plate. As the furnace, for example, SPX-1120 manufactured by APEX CORPORATION, VF-1000LP manufactured by Koyo Thermo Systems Co., Ltd., or the like can be used.

The resin material applied to the surface may be heated in an air atmosphere or in an inert gas atmosphere (nitrogen gas, argon gas, helium gas, or the like).

The heating time for the resin material applied to the surface is not particularly limited, and is, for example, 3 hours or less, and preferably 1 hour or less. The lower limit of the heating time is not particularly limited, and it can be set to, for example, 5 minutes.

In order to shorten the curing time of the resin material applied to the surface, the resin material applied to the surface may be irradiated with ultraviolet (UV) rays. As the ultraviolet light, ultraviolet light having a wavelength of from 170 nm to 230 nm, excimer light having a wavelength of 222 nm, excimer light having a wavelength of 172 nm, and the like are preferable. It is also preferable to carry out the ultraviolet irradiation in an inert gas atmosphere.

Whether or not the resin material is cured can be confirmed, for example, by measuring the peak intensity of specific bonds and structures by Fourier transform infrared spectroscopy (FT-IR). The specific bonds and structures include bonds and structures generated by a crosslinking reaction.

For example, in a case in which an amide bond, an imide bond, a siloxane bond, a tetrahydronaphthalene structure, an oxazole ring structure, or the like is formed, it can be determined that the resin material is cured, and this can be confirmed by measuring the peak intensities resulting from these bonds, structures, and the like using FT-IR.

The amide bond can be confirmed by the presence of vibration peaks at about 1650 cm⁻¹ and about 1520 cm⁻¹.

The imide bond can be confirmed by the presence of vibration peaks at about 1770 cm⁻¹ and about 1720 cm⁻¹.

The siloxane bond can be confirmed by the presence of vibration peaks between 1000 cm⁻¹ and 1080 cm⁻¹.

The tetrahydronaphthalene structure can be confirmed by the presence of vibration peaks between 1500 cm⁻¹.

The oxazole ring structure can be confirmed by the presence of vibration peaks at about 1625 cm⁻¹ and about 1460 cm-1

At least one of the first resin layer or the second resin layer formed by curing a resin material has preferably a siloxane bond and at least one selected from the group consisting of an ester bond, an ether bond, an amide bond and an imide bond, and more preferably has a siloxane bond and an imide bond.

The first resin layer and the second resin layer formed by curing a resin material have a sodium content and a potassium content each of 10 ppb by mass or less on an elemental basis. As long as the content of sodium or potassium is 10 mass ppb or less on an elemental basis, the occurrence of a problem in the electrical characteristics of a semiconductor device, such as a malfunction of a transistor, can be suppressed.

The amount of silicon at the surface of the first resin layer and the surface of the second resin layer are each independently preferably 20 atomic % or less, more preferably 15 atomic % or less, and still more preferably 10 atomic % or less.

The amount of silicon at the surface of the resin layer can be evaluated by measuring the atomic ratio using an X-ray photoelectron spectroscopy (XPS). Specifically, using an AXIS-NOVA (manufactured by KRATOS) as XPS, the atomic ratio can be measured from the peak intensity of the narrow spectrum when the total amount of each element detected in the wide spectrum is taken as 100%.

The thicknesses of the first resin layer and the second resin layer are each independently preferably from 0.001 μm to 8.0 μm, more preferably from 0.01 μm to 6.0 μm, and still more preferably from 0.03 μm to 5.0 μm. As the thicknesses of the first resin layer and the second resin layer are 0.001 μm or more, the bonding strength with the second inorganic material layer and other layers can be increased. As the thicknesses of the first resin layer and the second resin layer are 8.0 μm or less, it is possible to suppress the thickness variations of the resin layer when the resin layer is formed on a large-area substrate.

In a case in which an electrode is provided at a part of a surface of the first resin layer and a part of a surface of the second resin layer, the thicknesses of the first resin layer and the second resin layer are preferably from 0.01 μm to 8.0 μm, more preferably from 0.03 μm to 6.0 μm, and still more preferably from 0.05 μm to 5.0 μm, from the viewpoint of improving the bonding strength with the second inorganic material layer and other layers and suppressing the thickness variations of the first resin layer and the second resin layer.

In a case in which no electrodes are provided at the surface of the first resin layer and the surface of the second resin layer, the thicknesses of the first resin layer and the second resin layer are preferably from 0.001 μm to less than 1.0 μm, more preferably from 0.01 μm to 0.8 μm, and still more preferably from 0.03 μm to 0.6 μm, from the viewpoint of improving the bonding strength with the second inorganic material layer and other layers and suppressing the thickness variations of the first resin layer and the second resin layer.

From the viewpoints of facilitating to temporarily fix the first resin layer and the second inorganic material layer at a low temperature, as described below, and increasing the bonding strength between the first layered body and the second layered body in the substrate layered body, the first resin layer has preferably a functional group capable of forming a chemical bond at the surface of the first resin layer and more preferably at least one functional group selected from the group consisting of a silanol group (Si—OH group), an amino group, an epoxy group, a hydroxyl group, and a functional group having an unsaturated bond, and has still more preferably a silanol group from the viewpoint of heat resistance. These functional groups may be formed by a surface treatment after the formation of the first resin layer, or may be formed by a treatment with a silane coupling agent or the like. Alternatively, a compound containing these functional groups may be mixed into the resin composition.

Examples of the functional group having an unsaturated bond include a vinyl group, an allyl group, an acryl group, a methacryl group, and a styryl group.

The second resin layer may have the above functional group capable of forming a chemical bond at the surface of the second resin layer.

Whether or not the surface of the resin layer has an Si—OH group can be evaluated by surface analysis of the resin layer using time-of-flight secondary ion mass spectrometry (TOF-SIMS). Specifically, using PHI NANOTOF II (ULVAC-PHI, Inc.) as TOF-SIMS, the presence or absence of a peak at a mass-to-charge ratio (m/Z) of 45 can be used to evaluate whether or not the surface of the resin layer has an Si—OH group.

After forming the first resin layer or the second resin layer, the surface of at least one of the first resin layer or the second resin layer may be planarized. Examples of the planarization method include a fly-cutting method and a chemical mechanical polishing method (CMP). As the planarization method, one method may be used singly, or two or more methods used in combination.

After forming the first resin layer or the second resin layer, the surface of at least one of the first resin layer or the second resin layer may be cleaned. Examples of cleaning methods include wet cleaning with a rinse liquid, and dry cleaning with plasma or the like. Examples of the wet cleaning include ultrasonic cleaning using pure water and spin cleaning using a solvent such as NMP.

### (First Inorganic Material Layer and Second Inorganic Material Layer)

The first inorganic material layer is a layer disposed at another surface of the first substrate, and the second inorganic material layer is a layer disposed at another surface of the second substrate. For example, a first resin layer may be formed at one side of the first substrate, and then a first inorganic material layer may be formed at another side of the first substrate, or conversely, a first resin layer may be formed after the first inorganic material layer is formed. The same applies to the second substrate, and the order in which the second resin layer and the second inorganic material layer are formed is not particularly limited.

The materials of the first inorganic material layer and the second inorganic material layer are not particularly limited, and may be, for example, an inorganic material that is used when bonding inorganic materials together in a semiconductor substrate. Specifically, the first inorganic material layer and the second inorganic material layer may each independently contain at least one element selected from the group consisting of Si, Al, Ti, Zr, Hf, Fe, Ni, Cu, Ag, Au, Ga, Ge, Sn, Pd, As, Pt, Mg, In, Ta, and Nb, and preferably contain at least one element selected from the group consisting of Si, Ga, Ge, and As. The first inorganic material layer and the second inorganic material layer may contain oxides, carbides, nitrides, and the like of the aforementioned elements.

The materials of the first inorganic material layer and the second inorganic material layer may be the same as or different from each other.

A method of forming an inorganic material layer at the surface of the substrate is not particularly limited, and examples thereof include conventionally known methods for forming an inorganic material layer. For example, CVD, sputtering, AGD (aerosolized gas deposition), sol-gel method, anodization, pyrolysis, and the like can be mentioned.

### (Electrode)

The first layered body may include an electrode at a part of a surface of the first resin layer and a part of a surface of the first inorganic material layer, and the second layered body may include an electrode at a part of a surface of the second resin layer and a part of a surface of the second inorganic material layer. It is preferable that the electrode provided at the first resin layer is disposed so as to be in contact with the electrode provided at the second inorganic material layer in the step B.

A through hole may be created in the first layered body from the surface on the first resin layer side toward the surface on the first inorganic material layer side, and an electrode penetrating the first layered body may be provided in the through hole. A through hole may be created in the second layered body from the surface on the second resin layer side toward the surface on the second inorganic material layer side, and an electrode penetrating the second layered body may be provided in the through hole.

The material for the electrodes is not particularly limited, and examples thereof include conventionally known electrode materials. Specific examples thereof include copper, solder, tin, gold, silver, aluminum, indium, cobalt, and tungsten.

A method of providing an electrode at the first layered body and the second layered body is not particularly limited, and any conventionally known method can be used.

In the first layered body, an electrode may be formed at the surface to which the resin material is to be applied before the first resin layer is formed, or an electrode may be formed at the surface on which the first resin layer is formed after the first resin layer is formed. The same applies to the second layered body.

In the first layered body, an electrode may be formed at the surface on which the first inorganic material layer is to be formed before the first inorganic material layer is formed, or an electrode may be formed at the surface on which the first inorganic material layer is formed after the first inorganic material layer is formed. The same applies to the second layered body.

The electrode may be formed in a convex shape at the surface of the first substrate or the second substrate, may be formed in a state penetrating the first substrate or the second substrate, or may be formed in a state embedded in the first substrate or the second substrate.

In a case in which the electrode is formed before the resin layer or the inorganic material layer is formed, a configuration in which the electrode is provided at a part of a surface of the resin layer or a part of a surface of the inorganic material layer is achieved by removing the resin layer or inorganic material layer on the electrode. Examples of a method of removing the resin layer or inorganic material layer on a conductive layer include fly-cutting, chemical mechanical polishing (CMP), and plasma dry etching. As the removal method, one method may be used singly, or two or more methods used in combination. For example, in the fly-cutting method, a surface planer (DFS8910 (manufactured by Disco Corporation)) or the like can be used. In the case of using CMP, a slurry used may be, for example, a slurry containing silica or alumina, which is generally used for polishing resins, or a slurry containing hydrogen peroxide and silica, which is used for polishing metals. In the case of using plasma dry etching, fluorocarbon plasma, oxygen plasma, or the like may be used.

In the case of removing the resin layer or inorganic material layer on the electrode surface to expose the electrode, a reduction treatment of oxides on the electrode surface may be carried out, if necessary. Examples of the reduction treatment method include a method of heating the substrate at from 100° C. to 300° C. in an acid atmosphere such as formic acid, and a method of heating the substrate in a hydrogen atmosphere. These treatments may be carried out simultaneously with the step C described below.

In a case in which the electrode is formed after the resin layer or the inorganic material layer is formed, for example, a hole for forming an electrode may be formed by a known method at the surface of the substrate on which the resin layer is formed or at the surface of the substrate on which the inorganic material layer is formed, and an electrode may be formed in the formed hole. Examples of a method of forming a hole include dry etching using a gas and laser ablation.

Examples of a method of forming an electrode include electrolytic plating, electroless plating, sputtering, and an inkjet method.

In a case in which the resin material has photosensitivity, a hole in which an electrode is to be formed may be formed by photolithography in the resin material applied to at least one of the first substrate or the second substrate. After the resin material is cured so as to form at least one of the first resin layer or the second resin layer, an electrode may be formed in the formed hole.

The first layered body and the second layered body may be layered bodies that have been singulated by a dicing process, as necessary. For example, a dicer (DAD6340 (manufactured by Disco Corporation)) can be used for dicing.

### [Step B]

The method of producing a substrate layered body of the present disclosure includes a step B of bringing the first resin layer of the first layered body into contact with the second inorganic material layer of the second layered body, thereby layering the first layered body and the second layered body.

The step B is a step of bringing the first resin layer into contact with the second inorganic material layer before bonding the first layered body and the second layered body via the first resin layer and the second inorganic material layer in the step C described below. The first layered body and the second layered body are brought into contact with each other such that a desired positional relationship is achieved when the first layered body and the second layered body are bonded together.

For example, in a case in which the above-described electrode is provided at each of the first layered body and the second layered body, it is preferable to bring the first layered body and the second layered body into contact with each other such that an electrode provided at the first resin layer side is brought into contact with an electrode provided at the second inorganic material layer.

Before the first resin layer and the second inorganic material layer are brought into contact with each other in the step B, the curing rate of the first resin layer is preferably from 70% to 100%. This makes it possible to firmly bond the first layered body and the second layered body in the step C described below, and also makes it more difficult for misalignment of bonding position (misalignment) to occur during bonding.

The curing rate of the first resin layer is preferably 80% or more, more preferably 85% or more, particularly preferably 90% or more, and still more preferably 93% or more. In addition, the curing rate of the first resin layer may be 100%, 99% or less, 95% or less, or 90% or less.

The preferred range of the curing rate of the second resin layer is the same as the preferred range of the curing rate of the first resin layer. The curing rate of the second resin layer may be a curing rate before it is brought into contact with another layer (e.g., another inorganic material layer).

The curing rate of a resin layer (at least one of the first resin layer or the second resin layer) containing at least one selected from the group consisting of an amide bond, an imide bond, a siloxane bond, a tetrahydronaphthalene structure, an oxazole ring structure, an ester bond, and an ether bond is preferably 80% or more, more preferably 85% or more, particularly preferably 90% or more, and still more preferably 93% or more. The curing rate of a resin layer (at least one of the first resin layer or the second resin layer) containing a siloxane bond and at least one selected from the group consisting of an ester bond, an ether bond, an amide bond, and an imide bond is preferably 80% or more, more preferably 85% or more, particularly preferably 90% or more, and still more preferably 93% or more.

The curing rate of the first resin layer formed by curing a resin material may be confirmed by measuring the peak intensities of specific bonds and structures (the sum of the peak intensities when there are a plurality of peaks for imide, amide, and the like) in the resin material before being applied to the first substrate, the first resin layer before bringing the first resin layer into contact with the second inorganic material layer in the step B, and the first resin layer after the step C by Fourier transform infrared spectroscopy (FT-IR) and determining the rate of increase or decrease in the peak intensity. In a case in which a band-like peak is present that is difficult to separate for a siloxane bond or the like, the maximum peak intensity may be used.

Specifically, in a case in which specific bonds and structures are generated by the curing reaction, the increase rate of the peak intensity may be calculated by the following formula, and the calculated value may be regarded as the curing rate of the first resin layer.

$$Increase rate of peak strength ( Curing rate of first resin layer ) = [ ( Peak strength of specific bonds and structures of first resin layer before bringing first resin layer into contact with second inorganic material layer in step B ) / ( Peak strength of specific bonds and structures of first resin layer after heating at 300 ° C . for 1 hour in step C ) ] \times 100$$

The background signal can be removed by an ordinary method. Furthermore, an FT-IR measurement can be carried out by a transmission method or a reflection method, if necessary.

In the above-described increase rate of the peak intensity, when there are a plurality of bonds and structures that cause an increase in the peak intensity, the peak intensity may be interpreted as the total intensity of the plurality of peak intensities.

Before the first resin layer and the second inorganic material layer are brought into contact with each other in the step B, the composite elastic modulus of the first resin layer at 23° C. is preferably from 0.1 GPa to 20 GPa, and more preferably from 0.1 GPa to 10 GPa. As a result, voids formed when the first resin layer and the second inorganic material layer are brought into contact with each other in the step B tend to be absorbed by the first resin layer in the step C, thereby suppressing the generation of voids. This also makes it easier to temporarily fix the first resin layer and the second inorganic material layer at a low temperature, as described below.

The composite elastic modulus of the first resin layer at 23° C. is preferably 8 GPa or less and more preferably 6 GPa or less from the viewpoint of suppressing the generation of voids in a preferred manner. The composite elastic modulus of the first resin layer at 23° C. is preferably 0.1 GPa or more and more preferably 1 GPa or more from the viewpoint of suppressing misalignment in a preferred manner.

The preferred range of the composite elastic modulus at 23° C. of the second resin layer is the same as the preferred range of the composite elastic modulus at 23° C. of the first resin layer. The composite elastic modulus of the second resin layer at 23° C. may be a composite elastic modulus at 23° C. before being brought into contact with another layer (e.g., another inorganic material layer).

The composite elastic modulus of the resin layer at 23° C. can be measured by the method described below.

A resin composition containing a resin material is prepared, spin-coated on a silicon substrate, and then heated at 400° C. for 10 minutes, thereby preparing a measurement sample. For the prepared measurement sample, a nanoindenter (trade name: TI-950 TRIBOINDENTER manufactured by Hysitron, Berkovich-type indenter) is used for measuring an unloading-displacement curve at 23° C. under the condition of a test depth of 20 nm, and the composite elastic modulus at 23° C. is calculated from the maximum load and maximum displacement according to the calculation method in the reference literature (Handbook of Micro/nano Tribology (second Edition), edited by Bharat Bhushan, CRC Press).

Here, the composite elastic modulus is defined by the following Formula (1). In Formula (1), Er represents a composite elastic modulus, Ei represents aYoung's modulus of the indenter and is 1140 GPa, vi represents a Poisson's ratio of the indenter and is 0.07, and Es and vs represent a Young's modulus and a Poisson's ratio of the sample, respectively.

$$\frac{1}{{E}_{r}} = \frac{1 - {v}_{i}^{2}}{{E}_{i}} + \frac{1 - {v}_{s}^{2}}{{E}_{s}} \qquad ( 1 )$$

Before the first resin layer and the second inorganic material layer are brought into contact with each other in the step B, the surface roughness (Ra) of the first resin layer is preferably from 0.01 nm to 1.2 nm and more preferably from 0.1 nm to 1.0 nm. This makes it easier to temporarily fix the first resin layer and the second inorganic material layer at a low temperature, as described below.

The preferred range of the surface roughness (Ra) of the second resin layer is the same as the preferred range of the surface roughness (Ra) of the first resin layer. The surface roughness (Ra) of the second resin layer may be a surface roughness (Ra) before it is brought into contact with another layer (e.g., another inorganic material layer).

The surface roughness of the resin layer can be evaluated by morphological observation using a scanning probe microscope (SPM). Specifically, the surface roughness is determined by measuring a 3 μm×3 μm square area in a dynamic force microscope mode using SPA400 (manufactured by Hitachi High-Technologies Corporation) as an SPM.

The method of producing a substrate layered body of the present disclosure may include various steps described below before the above-described the step B. The following various steps are preferably carried out after the step A and before the step B.

The method of producing a substrate layered body of the present disclosure may include, before the step B, a step of performing a surface activation treatment on the second inorganic material layer. By performing the surface activation treatment, the bonding strength between the first resin layer and the second inorganic material layer can be increased. In particular, when providing electrodes at the bonding surfaces of the first layered body and the second layered body to bond the electrodes together, it is preferable to perform a surface activation treatment from the viewpoint of promoting the diffusion of metals such as copper contained in the electrodes to increase the bonding strength between the electrodes, and from the viewpoint of reducing the heating temperature during metal diffusion.

A surface activation treatment may also be performed on the first inorganic material layer in the first substrate. In particular, in the case of bonding the first inorganic material layer with another layer (e.g., another resin layer), a surface activation treatment may also be performed on the first inorganic material layer before bonding.

Specific examples of the surface activation treatment include plasma treatment and fast atom bombardment (FAB) treatment.

The method of producing a substrate layered body of the present disclosure may include, before the step B, a step of cleaning the second inorganic material layer to remove particles and the like. The above cleaning step is preferably carried out after the surface treatment step and before the step B.

The first inorganic material layer in the first substrate may also be cleaned. In particular, in the case of bonding the first inorganic material layer with another layer (e.g., another resin layer), the first inorganic material layer may be cleaned before bonding.

The cleaning method is not particularly limited, and examples thereof include wet cleaning using a solvent such as an alkaline cleaning solution, an acidic cleaning solution, a cleaning solution containing hydrofluoric acid, or a solution containing permanganic acid (desmear solution), wet cleaning using pure water, and dry cleaning using UV ozone, plasma, or the like.

The method of producing a substrate layered body of the present disclosure may include, before the step B, a step of providing a surface protective layer at the second inorganic material layer to prevent adhesion of foreign matter on the inorganic material layer (e.g., to prevent adhesion of foreign matter during dicing). The step of providing a surface protective layer is preferably carried out before the above-described cleaning step and before the step B.

The surface protective layer is not particularly limited as long as it can protect the second inorganic material layer, and examples thereof include water-soluble resins and photoresists that can be washed with organic solvents such as N-methyl-2-pyrrolidone (NMP). As the water-soluble resin, HOGOMAX manufactured by Disco Corporation may be used.

The second layered body provided with the surface protective layer may be subjected to a dicing process, if necessary, and the surface protective layer may be peeled off after the dicing process. In this case, it is preferable to peel off the surface protective layer after the dicing process, followed by performing the above-described cleaning step and the step B in this order after the surface protective layer has been peeled off.

The method of producing a substrate layered body of the present disclosure may include a step of temporarily fixing the first layered body and the second layered body after the step B and before the step C. The temporary fixing of the first layered body and the second layered body is preferably performed at a low temperature of from room temperature to 100° C., more preferably at a low temperature of from room temperature to 50° C., and still more preferably at room temperature.

In a case in which the first substrate and the second substrate include a silicon substrate, the surface energy of the bonded interface between the first layered body and the second layered body in a state in which the two layered bodies are temporarily fixed is preferably 0.05 J/m² or more, more preferably 0.1 J/m² or more, and even more preferably 0.15 J/m² or more, from the viewpoints of ease of handling in the step C, prevention of misalignment (misalignment of bonding position), prevention of contamination by foreign matter, and the like.

The surface energy (bonding strength) of the bonded interface can be determined by a blade insertion test according to the method described in the non-patent literature (M. P. Maszara, G. Goetz, A. Cavigila, and J. B. Mckitterick, Journal of Applied Physics, 64 (1988) 4943-4950). A blade having a thickness of from 0.1 mm to 0.3 mm is inserted into the bonded interface of the temporarily fixed layered body, and the distance from the blade tip to the layered body that has peeled off is measured using an infrared light source and an infrared camera. Then, the surface energy can be calculated based on the following formula:

$$γ = 3 \times {10}^{9} \times {t}_{b}^{2} \times {E}^{2} \times {t}^{6} / ( 32 \times {L}^{4} \times E \times {t}^{3} ) .$$

Here, γ represents a surface energy (J/m²), tb represents a blade thickness (m), E represents a Young's modulus (GPa) of the silicon substrate contained in the first substrate and the second substrate, t represents thicknesses (m) of the first substrate and the second substrate, and L represents a layered body peeling distance (m) from the blade tip.

### [Step C]

The method of producing a substrate layered body of the present disclosure includes a step C of heating the first layered body and the second layered body at 100° C. or more after the step B. This results in a substrate layered body in which the first layered body and the second layered body are bonded via the first resin layer and the second inorganic material layer.

The pressure when the first layered body and the second layered body are bonded is not particularly limited, but an absolute pressure of from 10-4 Pa to atmospheric pressure is preferable.

The absolute pressure is more preferably from 10-3 Pa to atmospheric pressure, still more preferably from 100 Pa to atmospheric pressure, and particularly preferably from 1000 Pa to atmospheric pressure.

The first layered body and the second layered body may be bonded together in an air atmosphere or in an inert gas (nitrogen gas, argon gas, helium gas, or the like) atmosphere.

In the step C, it is preferable to heat the first layered body and the second layered body at from 100° C. to 450° C. in a state in which the first resin layer and the second inorganic material layer are in contact with each other.

The above temperature refers to the temperature of the surface of the first substrate on which the first resin layer is formed.

The temperature is preferably from 100° C. to 400° C., more preferably from 130° C. to 350° C., still more preferably from 150° C. to 300° C., even still more preferably from 150 to 250° C., and particularly preferably from 150° C. to 200° C.

In a case in which the electrode provided at the first resin layer is disposed so as to be in contact with the electrode provided at the second inorganic material layer in the step B, the above-described temperature is preferably 130° C. or more, more preferably 150° C. or more, and still more preferably 200° C. or more. This tends to cause components (e.g., copper) contained in the electrode provided at the first resin layer side and the electrode provided at the second inorganic material layer to diffuse, increasing the bonding strength between the electrodes.

The heating in the step C can be carried out by an ordinary method using a furnace or a hot plate.

The heating in the step C may be carried out in an air atmosphere or in an inert gas atmosphere (nitrogen gas, argon gas, helium gas, or the like).

The heating time in the step C is not particularly limited, and is, for example, 3 hours or less, preferably 1 hour or less. The lower limit of the heating time is not particularly limited, and it can be set to, for example, 5 minutes.

In the step C, in order to increase the bonding strength between the first layered body and the second layered body, the first layered body and the second layered body may be pressurized in a state in which the first resin layer and the second inorganic material layer are in contact with each other. Pressurization and heating may be performed simultaneously.

The pressure for pressurizing the first layered body and the second layered body is not particularly limited, and is preferably from 0.1 MPa to 10 MPa and more preferably from 0.1 MPa to 5 MPa. As a pressure device, for example, TEST MINI PRESS manufactured by Toyo Seiki Seisaku-sho, Ltd. or the like may be used.

The method of producing a substrate layered body of the present disclosure may include, after the step C, a step of creating a through hole in the first layered body and the second layered body from the surface on the first inorganic material layer side toward the surface on the second resin layer side and forming an electrode penetrating the first layered body and the second layered body in the through hole. It is preferable that an electrode penetrating the first layered body and the second layered body is formed in the through hole by carrying out this step of forming an electrode in a case in which no electrodes are formed at the substrate layered body obtained in the step C

For example, a through hole penetrating the first layered body and the second layered body may be created by a known method, and an electrode may be formed in the created hole. Examples of a method of creating a hole include dry etching using a gas and laser ablation.

Examples of a method for forming an electrode penetrating the first layered body and the second layered body include electrolytic plating, electroless plating, sputtering, and an inkjet method.

The material for the electrode penetrating the first layered body and the second layered body is not particularly limited, and examples thereof include conventionally known electrode materials. Specific examples thereof include copper, solder, tin, gold, silver, aluminum, indium, cobalt, and tungsten.

In the method of producing a substrate layered body of the present disclosure, another substrate, another layered body, or the like may be further layered at a surface of the first inorganic material layer side and a surface of the second resin layer for at least one of the first substrate or the second substrate. Preferred materials for another substrate are the same as those for the first substrate and the second substrate. Preferred aspects of another layered body are the same as the preferred aspects of the first layered body and the second layered body.

In the method of producing a substrate layered body of the present disclosure, after the step C, a thinning process (back grinding) may be performed on the surface of the substrate layered body, if necessary.

### (Examples of Layered Structure of Substrate Layered Body)

Examples of the layered structure of the substrate layered body for various applications are shown below. The bonding layer means a layer in a bonded state consisting of an inorganic material layer and a resin layer:
for MEMS packaging: Si/bonding layer/Si, SiO₂/bonding layer/Si, SiO₂/bonding layer/SiO₂, Cu/bonding layer/Cu;
for microchannels: PDMS/bonding layer/PDMS, PDMS/bonding layer/SiO₂;
for CMOS image sensors: SiO₂/bonding layer/SiO₂, Si/bonding layer/Si, SiO₂/bonding layer/Si;
for through silicon vias (TSV): SiO₂ (with Cu electrode)/bonding layer/SiO₂ (with Cu electrode), Si (with Cu electrode)/bonding layer/Si (with Cu electrode);
for optical devices: (InGaAlAs, InGaAs, InP, GaAs)/bonding layer/Si;
for LEDs: (InGaAlAs, GaAs, GaN)/bonding layer/Si, (InGaAlAs, GaAs, GaN)/bonding layer/SiO₂, (InGaAlAs, GaAs, GaN)/bonding layer/(Au, Ag, Al), (InGaAlAs, GaAs, GaN)/bonding layer/sapphire.

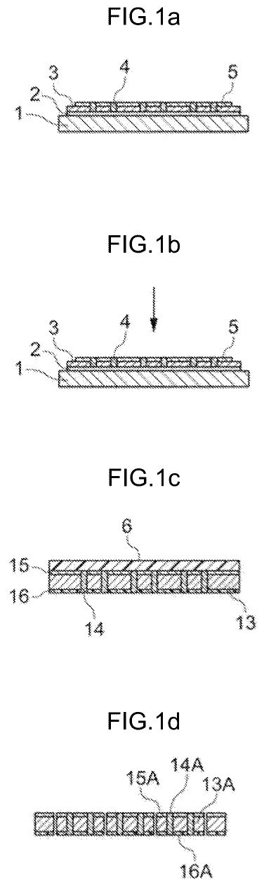

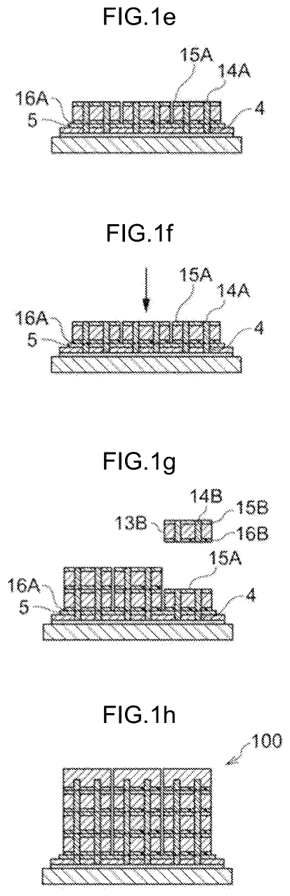

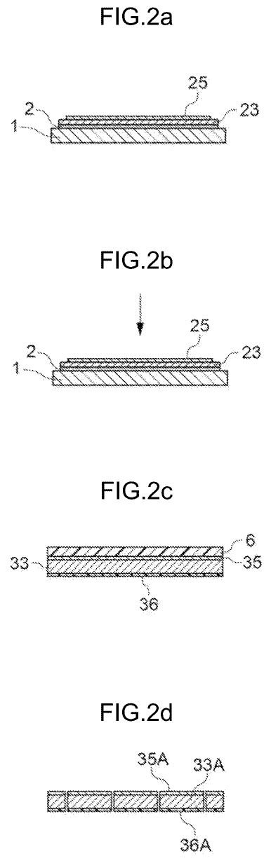

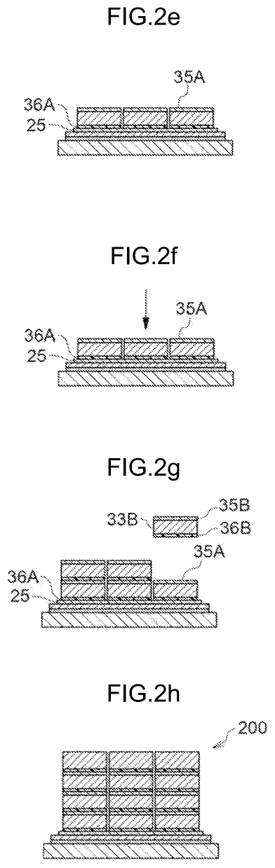

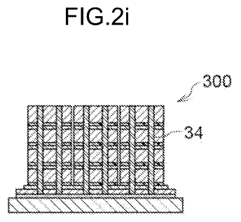

An example of the method of producing a substrate layered body will be described below with reference to FIGS. 1a to 1h and 2a to 2i. Note that the present disclosure is not limited to the configurations shown in the drawings. Furthermore, the sizes of the members in FIGS. 1a to 1h and 2a to 2i are conceptual, and the relative relationships between the sizes of the members are not limited thereto. In addition, in each drawing, members having substantially the same functions are given the same reference numerals throughout the drawings, and duplicated explanations may be omitted.

### Example 1 of Method of Producing Substrate Layered Body

Example 1 of the method of producing a substrate layered body will be described below with reference to FIGS. 1a to 1h. As shown in FIG. 1a, a wafer 3 having a penetrating electrode 4 and a planarized surface is prepared. At a surface of the wafer 3, an inorganic material layer 5 such as an oxide film is formed. The wafer 3 having the electrode 4 is fixed to a carrier 1 via a temporary fixing material 2.

Next, as shown in FIG. Tb, the inorganic material layer 5 at the surface of the wafer 3 is subjected to a surface activation treatment as described above.

Furthermore, a layered body is prepared, which is provided with an inorganic material layer 15, a wafer 13, and a resin layer 16 in this order, and further includes an electrode 14 penetrating the wafer 13. As shown in FIG. Tc, a surface protective material 6 is disposed at the inorganic material layer 15 side of the layered body.

As shown in FIG. Td, the layered body is diced, and then the surface protective material 6 is peeled off, thereby obtaining singulated layered bodies. Each singulated layered body includes an inorganic material layer 15A, a wafer 13A, and a resin layer 16A, which are each singulated, in this order. Furthermore, each singulated layered body includes an electrode 14A penetrating the singulated layered body. From the viewpoint of removing foreign matter, the surface of the singulated layered body may be cleaned with pure water, a solvent, or the like after the surface protective material 6 has been peeled off. At this time, a plurality of singulated layered bodies may be cleaned collectively while being loaded on a frame.

Next, as shown in FIG. Te, the inorganic material layer 5 at the surface of the wafer 3 and the resin layer 16A of each singulated layered body are brought into contact with each other and temporarily fixed. At this time, a plurality of singulated layered bodies may be temporarily fixed in the width direction and the length direction.

As shown in FIG. 1f, the inorganic material layer 15A of the singulated layered body temporarily fixed to the wafer 3 is subjected to a surface activation treatment as described above. After surface activation, the surface of the inorganic material layer 15A may be cleaned with pure water, a solvent, or the like.

By the procedures shown in FIGS. 1c and 1d, singulated layered bodies are obtained, each of which includes an inorganic material layer 15B, a wafer 13B, and a resin layer 16B in this order. Each singulated layered body includes an electrode 14B penetrating the singulated layered body. As shown in FIG. 1g, the inorganic material layer 15A of a singulated layered body temporarily fixed to the wafer 3 and the resin layer 16B of a singulated layered body are brought into contact with each other and temporarily fixed. At this time, a plurality of singulated layered bodies may be temporarily fixed in the width direction and the length direction.

By repeating the treatments shown in FIGS. 1f and 1g, the singulated layered bodies are layered in a temporarily fixed state in the height direction. After layering the singulated layered bodies is completed, the layered body including the singulated layered bodies is heated at 100° C. or more. This allows the wafer 3 and the singulated wafers 13B to be bonded via the inorganic material layer 5 and the resin layer 16A, and the singulated layered bodies layered in the height direction to be bonded via a singulated inorganic material layer and a singulated resin layer. From the viewpoint of increasing the bonding strength between the electrodes, it is preferable to heat the layered body including the singulated layered bodies at 130° C. or more. This tends to cause components (e.g., copper) contained in each electrode to diffuse, increasing the bonding strength between the electrodes.

As a result of the above, a substrate layered body 100 is obtained as shown in FIG. 1h.

### Example 2 of Method of Producing Substrate Layered Body

Example 2 of the method of producing a substrate layered body will be described below with reference to FIG. 2a to 2i. Example 2 of the method of producing a substrate layered body differs from Example 1 of the method of producing a substrate layered body described above in that a wafer having no electrodes is used, and finally, a through hole is created in a substrate layered body having no electrodes, and an electrode is provided in the through hole.

As shown in FIG. 2a, a wafer 23 having a planarized surface is prepared. At a surface of the wafer 23, an inorganic material layer 25 such as an oxide film is formed. The wafer 23 is fixed to a carrier 1 via a temporary fixing material 2.

Next, as shown in FIG. 2b, the inorganic material layer 25 at the surface of the wafer 23 is subjected to a surface activation treatment as described above.

Furthermore, a layered body is prepared, which is provided with an inorganic material layer 35, a wafer 33, and a resin layer 36 in this order. As shown in FIG. 2c, a surface protective material 6 is disposed at the inorganic material layer 35 side of the layered body.

As shown in FIG. 2d, the layered body is diced, and then the surface protective material 6 is peeled off, thereby obtaining singulated layered bodies. Each singulated layered body includes an inorganic material layer 35A, a wafer 33A, and a resin layer 36A, which are each singulated, in this order. From the viewpoint of removing foreign matter, the surface of the singulated layered body may be cleaned with pure water, a solvent, or the like after the surface protective material 6 has been peeled off. At this time, a plurality of singulated layered bodies may be cleaned collectively while being loaded on a frame.

Next, as shown in FIG. 2e, the inorganic material layer 25 at the surface of the wafer 23 and the resin layer 36A of each singulated layered body are brought into contact with each other and temporarily fixed. At this time, a plurality of singulated layered bodies may be temporarily fixed in the width direction and the length direction.

As shown in FIG. 2f, the inorganic material layer 35A of the singulated layered body temporarily fixed to the wafer 23 is subjected to a surface activation treatment as described above. After surface activation, the surface of the inorganic material layer 35A may be cleaned with pure water, a solvent, or the like.

By the procedures shown in FIGS. 2c and 2d, singulated layered bodies are obtained, each of which includes an inorganic material layer 35B, a wafer 33B, and a resin layer 36B in this order. As shown in FIG. 2g, the inorganic material layer 35A of a singulated layered body temporarily fixed to the wafer 23 and the resin layer 36B of a singulated layered body are brought into contact with each other and temporarily fixed. At this time, a plurality of singulated layered bodies may be temporarily fixed in the width direction and the length direction.

By repeating the treatments shown in FIGS. 2f and 2g, the singulated layered bodies are layered in a temporarily fixed state in the height direction. After layering the singulated layered bodies is completed, the layered body including the singulated layered bodies is heated at 100° C. or more. This allows the wafer 23 and the singulated wafers 33B to be bonded via the inorganic material layer 25 and the resin layer 36A, and the singulated layered bodies layered in the height direction to be bonded via a singulated inorganic material layer and a singulated resin layer. As a result, a substrate layered body 200 is obtained as shown in FIG. 2h.

Furthermore, through holes are created, which penetrate the singulated layered bodies layered on the substrate layered body 200 in the height direction. Examples of a method of creating a through hole include dry etching using a gas and laser ablation. Next, electrodes 34 are formed in the through holes so as to penetrate the singulated layered bodies layered.

As a result of the above, as shown in FIG. 2i, a substrate layered body 300 having electrodes 34 penetrating the singulated layered bodies is obtained.

### (Substrate Layered Body)

The substrate layered body of the present disclosure includes: a first layered body having a first resin layer, a first substrate, and a first inorganic material layer in this order, in which the first resin layer is disposed at one surface and the first inorganic material layer is disposed at another surface; and
a second layered body having a second resin layer, a second substrate, and a second inorganic material layer in this order, in which the second resin layer is disposed at one surface and the second inorganic material layer is disposed at another surface,
in which the first layered body and the second layered body are layered via the first resin layer of the first layered body and the second inorganic material layer of the second layered body.

The first and second layered bodies in the substrate layered body of the present disclosure may be layered bodies that are mounted three-dimensionally on a substrate such as a wafer, examples thereof including the first and second layered bodies used in the above-described method of producing a substrate layered body of the present disclosure. Preferred aspects of the first and second layered bodies in the substrate layered body are the same as those of the first and second layered bodies in the above-described method of producing a substrate layered body of the present disclosure.

For example, specific examples of the first and second layered bodies in the substrate layered body include the layered bodies as shown in FIG. 1c or FIG. 2c and singulated layered bodies as shown in FIGS. 1d and 2d.

The first or second layered body in the substrate layered body of the present disclosure is preferably a layered body for three-dimensional semiconductor devices.

In the substrate layered body of the present disclosure, it is preferable that the first layered body includes an electrode at a part of a surface of the first resin layer and a part of a surface of the first inorganic material layer, and
the second layered body includes an electrode at a part of a surface of the second resin layer and a part of a surface of the second inorganic material layer.

Preferred aspects of the electrode are the same as those of the electrode in the above-described method of producing a substrate layered body of the present disclosure

### <Modified Example of Method of Producing Substrate Layered Body>

The Modified Example of the method of producing a substrate layered body of the present disclosure differs from the above-described method of producing a substrate layered body of the present disclosure in that a layered body (third layered body) in which a first resin layer, a first substrate, and a third resin layer are layered in this order is used instead of the first layered body, and a layered body (third layered body) in which a second resin layer, a first substrate, and a fourth resin layer are layered in this order is used instead of the second layered body. In other words, in the layered body (third layered body), the first inorganic material layer of the first layered body is replaced by the third resin layer, and in the layered body (fourth layered body), the second inorganic material layer of the second layered body is replaced by the fourth resin layer. In the Modified Example, a substrate layered body is obtained by bonding the first resin layer and the fourth resin layer in the step C.

In the Modified Example, it is preferable that the first resin layer and the fourth resin layer have different resin compositions from each other, and a resin material used for forming the first resin layer and a resin material used for forming the fourth resin layer have different resin compositions from each other. This tends to favorably suppress warping of the substrate layered body even in a case in which the third layered body and the fourth layered body have small thicknesses.

The resin material used for forming the first resin layer is preferably a resin material capable of forming a resin layer having a composite elastic modulus at 23° C. of from 0.1 GPa to 10 GPa. In other words, the composite elastic modulus of the first resin layer at 23° C. is preferably from 0.1 GPa to 10 GPa.

Preferred conditions for the resin material used for forming the first resin layer and for the first resin layer are the same as those described in the above-described method of producing a substrate layered body of the present disclosure.

The resin material used for forming the fourth resin layer is not particularly limited as long as it has a composition different from that of the resin material used for forming the first resin layer. Examples thereof include, but are not particularly limited to: materials in which a bond or a structure is formed by crosslinking, such as polyimide, polyamide, polyamideimide, parylene, polyarylene ether, tetrahydronaphthalene, and octahydroanthracene; materials in which a nitrogen ring-containing structure is formed, such as polybenzoxazal and polybenzoxazine; materials in which a bond or a structure, such as Si—O, is formed by crosslinking; and organic materials such as siloxane-modified compounds; and benzocyclobutene and epoxy compounds.

The resin material used for forming the fourth resin layer is preferably a material in which a polyimide bond is formed by crosslinking, benzocyclobutene, an epoxy compound, a siloxane-modified compound, or the like. The material in which a polyimide bond is formed by crosslinking is preferably a siloxane compound in which a polyimide bond is formed by crosslinking, and the siloxane-modified compound is preferably an epoxy-modified siloxane.

### EXPLANATION OF REFERENCE NUMERALS

1: Carrier, 2: Temporary Fixing Material, 3: Wafer, 4: Electrode, 5: Inorganic Material Layer, 6: Surface Protective Material, 13: Wafer, 13A: Wafer, 13B: Wafer, 14: Electrode, 14A: Electrode, 14B: Electrode, 15: Inorganic Material Layer, 15A: Inorganic Material Layer, 15B: Inorganic Material Layer, 16: Resin Layer, 16A: Resin Layer, 16B: Resin Layer, 23: Wafer, 25: Inorganic Material Layer, 33: Wafer, 33A: Wafer, 33B: Wafer, 34: Electrode, 35: Inorganic Material Layer, 35A: Inorganic Material Layer, 35B: Inorganic Material Layer, 36: Resin Layer, 36A: Resin Layer, 36B: Resin Layer, 100: Substrate Layered Body, 200: Substrate Layered Body, 300: Substrate Layered Body

The disclosure of Japanese Patent Application No. 2022-109052, filed Jul. 6, 2022, is incorporated herein by reference in its entirety. All publications, patent applications, and technical standards mentioned in this specification are herein incorporated by reference to the same extent as if each individual publication, patent application, or technical standard was specifically and individually indicated to be incorporated by reference.

1. A method of producing a substrate layered body, comprising:
preparing: a first layered body in which a first resin layer, a first substrate, and a first inorganic material layer are layered in this order, the first resin layer is disposed at one surface, and the first inorganic material layer is disposed at another surface; and a second layered body in which a second resin layer, a second substrate, and a second inorganic material layer are layered in this order, the second resin layer is disposed at one surface, and the second inorganic material layer is disposed at another surface;
bringing the first resin layer of the first layered body and the second inorganic material layer of the second layered body into contact with each other, thereby layering the first layered body and the second layered body; and
heating the first layered body and the second layered body at 100° C. or more after the layering of the first layered body and the second layered body.

2. The method of producing a substrate layered body according to claim 1,
wherein the first layered body comprises an electrode at a part of a surface of the first resin layer and a part of a surface of the first inorganic material layer, and
wherein the second layered body comprises an electrode at a part of a surface of the second resin layer and a part of a surface of the second inorganic material layer.

3. The method of producing a substrate layered body according to claim 2, the method comprising performing a surface activation treatment on the second inorganic material layer before the layering of the first layered body and the second layered body.

4. The method of producing a substrate layered body according to claim 1, the method comprising, after the heating, creating a through hole in the first layered body and the second layered body from a surface on a side of the first inorganic material layer toward a surface on a side of the second resin layer and forming an electrode penetrating the first layered body and the second layered body in the through hole.

5. The method of producing a substrate layered body according to claim 1, the method comprising cleaning the second inorganic material layer before the layering of the first layered body and the second layered body.

6. The method of producing a substrate layered body according to claim 1, the method comprising providing a surface protective layer at the second inorganic material layer before the layering of the first layered body and the second layered body.

7. The method of producing a substrate layered body according to claim 1, wherein, before the first resin layer and the second inorganic material layer are brought into contact with each other, the first resin layer has a composite elastic modulus at 23° C. of from 0.1 GPa to 20 GPa.

8. The method of producing a substrate layered body according to claim 1, wherein, before the first resin layer and the second inorganic material layer are brought into contact with each other, the first resin layer has a curing rate of from 70% to 100%.

9. The method of producing a substrate layered body according to claim 1, wherein, before the first resin layer and the second inorganic material layer are brought into contact with each other, the first resin layer has a surface roughness (Ra) of from 0.01 nm to 1.2 nm.

10. The method of producing a substrate layered body according to claim 1, wherein the first resin layer has at least one functional group selected from the group consisting of a silanol group, an amino group, an epoxy group, a hydroxyl group, and a functional group having an unsaturated bond, on a surface thereof.

11. The method of producing a substrate layered body according to claim 1, wherein the first resin layer comprises:
a siloxane bond; and
at least one selected from the group consisting of an ester bond, an ether bond, an amide bond, and an imide bond.

12. The method of producing a substrate layered body according to claim 1, wherein the second inorganic material layer contains at least one element selected from the group consisting of Si, Ga, Ge, and As.

13. A substrate layered body, comprising:
a first layered body having a first resin layer, a first substrate, and a first inorganic material layer in this order, in which the first resin layer is disposed at one surface and the first inorganic material layer is disposed at another surface; and
a second layered body having a second resin layer, a second substrate, and a second inorganic material layer in this order, in which the second resin layer is disposed at one surface and the second inorganic material layer is disposed at another surface,
wherein the first layered body and the second layered body are layered via the first resin layer of the first layered body and the second inorganic material layer of the second layered body.

14. The substrate layered body according to claim 13,
wherein the first layered body comprises an electrode at a part of a surface of the first resin layer and a part of a surface of the first inorganic material layer, and
wherein the second layered body comprises an electrode at a part of a surface of the second resin layer and a part of a surface of the second inorganic material layer.
